(19) United States
(12) Patent Application Publication
(10) Pub. No.: US 2026/0015710 A1
(43) Pub. Date: Jan. 15, 2026

(54) SUPERHYDROPHOBIC SUBSTRATES AND METHODS FOR PRODUCING THE SAME

(71) Applicant: University of Virginia Patent Foundation, Charlottesville, VA (US)

(72) Inventors: Mool C. GUPTA, Keswick, VA (US); Narayana Raju GOTTUMUKKALA, Ayer, MA (US); Anustup CHAKRABORTY, Charlottesville, VA (US)

(21) Appl. No.: 18/875,254

(22) PCT Filed: Jun. 30, 2023
(86) PCT No.: PCT/US2023/069460

§ 371 Date: Dec. 16, 2024

Related U.S. Application Data
(60) Provisional application No. 63/357,237, filed on Jun. 30, 2022.

(51) Int. Cl. C23C 14/28; C03C 15/00; C03C 17/00; C03C 17/30; C23C 14/02; C23C 14/12; C23C 14/54

(52) U.S. Cl. CPC C23C 14/28; C03C 15/00; C03C 17/001; C03C 17/30; C23C 14/022; C23C 14/024; C23C 14/12; C23C 14/54; C03C 2217/76; C03C 2218/151; C03C 2218/31; C03C 2218/355

(57) ABSTRACT

In one aspect, the disclosure relates to methods for producing hydrophobic or superhydrophobic surfaces on an article. The method involves laser depositing hydrophobic materials on at least one surface of the article. By varying the laser parameters as well as the surface of the where the hydrophobic material is to be laser deposited, the hydrophobic properties of the surface can be modified. The starting substrate could be hydrophilic or superhydrophilic.

### CROSS-REFERENCE TO RELATED APPLICATIONS

This application claims the benefit of U.S. Provisional Application No. 63/357,237, filed on Jun. 30, 2022, which is incorporated herein by reference in its entirety.

### STATEMENT REGARDING FEDERALLY SPONSORED RESEARCH OR DEVELOPMENT

This invention was made with government support under grant number C15-2B00-UVA, a subaward of NNL09AA00A, and 80LARC1700004, awarded by the National Aeronautics and Space Administration. The government has certain rights in the invention.

### BACKGROUND

Superhydrophobic surfaces have important applications in the areas of anti-icing, corrosion resistance, anti-biofouling, fluid flow drag reduction, solar panels cleaning, wind blades ice protection, batteries for energy storage, textiles, and more. Various materials have been identified as hydrophobic materials, and methods have been developed for the fabrication of superhydrophobic surfaces using these starting materials.

Several methods, including chemical etching, lithography, 3-D printing, plasma treatment, and the like, have previously been demonstrated to create superhydrophobic surfaces. However, these methods require multiple steps, generate thick coatings that require greater materials inputs and costs to produce, and produce surfaces that are typically opaque to visual inspection. These methods may further require pre-treatment of surfaces to microtexture the surfaces prior to chemical treatments, may require hot embossing steps, and often require the use of acids and/or other chemicals.

What is needed is a simplified or single-step process that provides large area coverage with high throughput, that can produce surface micro and/or nanotextures and a hydrophobic coating in a single step, and that can produce optically transparent superhydrophobic surfaces. The method would ideally allow for the formation of microscale patterns and would make use of films that are only a few microns thick, thus requiring fewer materials. An ideal method would not require the use of acids. These needs and other needs are satisfied by the present disclosure.

### SUMMARY

In accordance with the purpose(s) of the present disclosure, as embodied and broadly described herein, the disclosure, in one aspect, relates to methods for producing superhydrophobic surfaces on an article. The method involves laser depositing hydrophobic materials on at least one surface of the article. By varying the laser parameters as well as the surface where the hydrophobic material is to be laser deposited, the hydrophobic properties of the surface can be modified.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described embodiments are usable in all aspects of the disclosure taught herein. Furthermore, the individual features of the dependent claims, as well as all optional and preferred features and modifications of the described embodiments are combinable and interchangeable with one another.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 shows a schematic diagram of the disclosed laser microtexturing process setup.

FIGS. 2A-2D show a schematic representation for producing the superhydrophobic substrates described herein.

FIG. 3 shows an optical transmission experimental measurement setup useful in the disclosed method.

FIGS. 4A-4D show deposited PDMS micro/nano particles on glass at different fluences using UV laser. The speed, frequency and the line-spacing were kept constant at 200 mm/s, 50 kHz and 20 μm respectively. (FIG. 4A) 1.12 mJ/cm²; (FIG. 4B) 1.68 mJ/cm²; (FIG. 4C) 1.98 mJ/cm²; (FIG. 4D) 2.28 mJ/cm². FIG. 4E shows a magnified SEM images of a PDMS micro/nanoparticle coating.

FIG. 5 shows contact angle of water on PDMS micro/nanoparticles deposited on aluminum (left), glass (right), and PMMA (bottom) surfaces.

FIGS. 6A-6C show PDMS micro/nanoparticles distribution at spacer thickness of (FIG. 6A) 1 mm, (FIG. 6B) 5 mm, and (FIG. 6C) 8 mm.

FIGS. 7A-7C show SEM images of the cross-section of the laser-ablated PDMS micro/nanoparticles coating with spacer thicknesses of (FIG. 7A) 1 mm, (FIG. 7B) 5 mm, and (FIG. 7C) 8 mm.

FIG. 8 shows XPS spectrum showing the peaks for the different elements (C, Si, and O).

Spectra are shown only from 0 to 600 eV.

FIGS. 9A-9B show optical transmission measurements on (FIG. 9A) silica and (FIG. 9B) PMMA.

FIG. 10 shows nominal ultimate shear strength (T_{Max}) of different coating thicknesses.

FIG. 11 shows SEM images of deposited PDMS lines on glass with a line width of 500 μm (left) and 200 μm (right).

FIGS. 12A-12C show SEM images showing the effect of the curing time of the poured PDMS on the laser-deposited PDMS micro/nanoparticles. The PDMS lines were deposited after curing the poured PDMS on glass for (FIG. 12A) 15 min, (FIG. 12B) 20 min, and (FIG. 12C) 25 min.

FIG. 13 shows a laser experimental setup with a galvanometer that can control laser scanning in 2D directions for laser processing of aluminum substrates.

FIG. 14 shows a schematic experimental setup of water drop flow measurement on plasma treated samples.

FIGS. 15A-15B show a top-view of textured aluminum surface at fluence of (FIG. 15A) 1.75 J/cm² and (FIG. 15B) 2.25 J/cm².

FIG. 16 shows a top-view of textured aluminum surface at fluence of 1.75 J/cm².

FIGS. 17A-17D show a water drop sitting on the surface of glass (FIG. 17A) or aluminum (FIG. 17C) textured at a fluence of 2.25 J/cm² and glass (FIG. 17B) or aluminum (FIG. 17D) textured at a fluence of 1.75 J/cm².

FIG. 18 shows a top-view of microtextured aluminum surface prior to coating with PDMS.

FIGS. 19A-19C show the cross-sectional overlap of two pulsed laser beams at different percentages of overlap.

Additional advantages of the invention will be set forth in part in the description which follows, and in part will be obvious from the description, or can be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### DETAILED DESCRIPTION

Many modifications and other embodiments disclosed herein will come to mind to one skilled in the art to which the disclosed compositions and methods pertain having the benefit of the teachings presented in the foregoing descriptions and the associated drawings. Therefore, it is to be understood that the disclosures are not to be limited to the specific embodiments disclosed and that modifications and other embodiments are intended to be included within the scope of the appended claims. The skilled artisan will recognize many variants and adaptations of the aspects described herein. These variants and adaptations are intended to be included in the teachings of this disclosure and to be encompassed by the claims herein.

Although specific terms are employed herein, they are used in a generic and descriptive sense only and not for purposes of limitation.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure.

Any recited method can be carried out in the order of events recited or in any other order that is logically possible. That is, unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present invention is not entitled to antedate such publication by virtue of prior invention. Further, the dates of publication provided herein can be different from the actual publication dates, which can require independent confirmation.

While aspects of the present disclosure can be described and claimed in a particular statutory class, such as the system statutory class, this is for convenience only and one of skill in the art will understand that each aspect of the present disclosure can be described and claimed in any statutory class.

It is also to be understood that the terminology used herein is for the purpose of describing particular aspects only and is not intended to be limiting. Unless defined otherwise, all technical and scientific terms used herein have the same meaning as commonly understood by one of ordinary skill in the art to which the disclosed compositions and methods belong. It will be further understood that terms, such as those defined in commonly used dictionaries, should be interpreted as having a meaning that is consistent with their meaning in the context of the specification and relevant art and should not be interpreted in an idealized or overly formal sense unless expressly defined herein.

Prior to describing the various aspects of the present disclosure, the following definitions are provided and should be used unless otherwise indicated. Additional terms may be defined elsewhere in the present disclosure.

### Definitions

As used herein, “comprising” is to be interpreted as specifying the presence of the stated features, integers, steps, or components as referred to, but does not preclude the presence or addition of one or more features, integers, steps, or components, or groups thereof. Moreover, each of the terms “by”, “comprising,” “comprises”, “comprised of,” “including,” “includes,” “included,” “involving,” “involves,” “involved,” and “such as” are used in their open, non-limiting sense and may be used interchangeably. Further, the term “comprising” is intended to include examples and aspects encompassed by the terms “consisting essentially of” and “consisting of.” Similarly, the term “consisting essentially of” is intended to include examples encompassed by the term “consisting of.

As used in the specification and the appended claims, the singular forms “a,” “an” and “the” include plural referents unless the context clearly dictates otherwise. Thus, for example, reference to “a substrate,” “a polymer,” or “a laser fluence,” includes, but is not limited to, mixtures, combinations, and/or series of two or more such substrates, polymers, or laser fluences, and the like.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

When a range is expressed, a further aspect includes from the one particular value and/or to the other particular value. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y’. The range can also be expressed as an upper limit, e.g. ‘about x, y, z, or less’ and should be interpreted to include the specific ranges of ‘about x’, ‘about y’, and ‘about z’ as well as the ranges of ‘less than x’, less than y’, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y’, and ‘greater than z’. In addition, the phrase “about ‘x’ to ‘y’”, where ‘x’ and ‘y’ are numerical values, includes “about ‘x’ to about ‘y’”.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the terms “about,” “approximate,” “at or about,” and “substantially” mean that the amount or value in question can be the exact value or a value that provides equivalent results or effects as recited in the claims or taught herein. That is, it is understood that amounts, sizes, formulations, parameters, and other quantities and characteristics are not and need not be exact but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In such cases, it is generally understood, as used herein, that “about” and “at or about” mean the nominal value indicated ±10% variation unless otherwise indicated or inferred. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

Disclosed are the components to be used to prepare the compositions of the invention as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the invention. Thus, if there are a variety of additional steps that can be performed it is understood that each of these additional steps can be performed with any specific embodiment or combination of embodiments of the methods of the invention.

It is understood that the compositions disclosed herein have certain functions. Disclosed herein are certain structural requirements for performing the disclosed functions, and it is understood that there are a variety of structures that can perform the same function that are related to the disclosed structures, and that these structures will typically achieve the same result.

The term “laser” as used herein is light produced from a laser device.

As used herein, the terms “optional” or “optionally” means that the subsequently described event or circumstance can or cannot occur, and that the description includes instances where said event or circumstance occurs and instances where it does not.

Unless otherwise specified, temperatures referred to herein are based on atmospheric pressure (i.e., one atmosphere).

### Methods for Producing Superhydrophobic Materials

Described herein are methods for producing superhydrophobic surfaces on an article. The method involves laser depositing hydrophobic materials on at least one surface of the article. By varying the laser parameters as well as the surface of the target substrate, the hydrophobic properties of the surface can be modified.

In one aspect, the method involves
(a) applying a coating of the hydrophobic material on a second surface of a first glass substrate having a first surface and a second surface;
(b) positioning the second surface of the first glass substrate in proximity to a first surface of a target substrate; and
(c) applying a depositing laser to the first surface of the first glass substrate, wherein the hydrophobic material on the second surface of the first glass substrate are converted to hydrophobic particles and deposited on the first surface of the target substrate.

The selection of the target substrate can vary and depend upon the application of the superhydrophobic article. In one aspect, the target substrate is optically transparent such as, for example, glass. In another aspect, the target substrate comprises aluminum, metals, polymers, ceramics, composites, alloys, or any combination thereof.

Prior to depositing the hydrophobic material on the target substrate, the first surface of the target substrate can be pre-treated to enhance or modify one or more properties of the hydrophobic coating produced on the target substrate.

In one aspect, the first surface of the target substrate is treated with a high-energy discharge treatment to modify the surface energy, for example a flame treatment, a corona treatment, a plasma treatment, or a combination thereof prior to laser deposition of the hydrophobic material. Corona treatment (also referred to as air plasma treatment) is a surface modification technique that uses a low temperature corona discharge plasma to impart changes in the properties of a surface. The corona plasma is generated by the application of high voltage to an electrode or array of electrodes having a sharp tip. Plasma treatment can be performed in an evacuated enclosure or chamber or in the presence of air. Exemplary methods for surface treating the target substrate are provided in the Examples.

In another aspect, the first surface of the target substrate is subjected to a microtexturizing laser to produce a microtextured surface prior to laser deposition of the hydrophobic material. In one aspect, the method involves subjecting the first surface of the target substrate to a pulsed laser at a controlled overlap of each pulsed laser to produce the microtextured surface.

The morphology of the microtextured surface can be varied by controlling the microtexturizing laser processing parameters. In one aspect, the microtexturized surface is composed of a plurality of features. The features present on the microtextured surface can have a variety of shapes and dimensions.

In one aspect, the average height of the features is about 0.1 μm to about 50 μm across the microtextured surface, or about 0.1 μm, 1 μm, 5 μm, 10 μm, 20 μm, 30 μm, 40 μm, or 50 μm, where any value can be a lower and upper endpoint of a range (e.g., 10 μm to 30 μm). In another aspect, the average spacing between each of the features is from about 0.1 μm to about 50 μm, or about 0.1 μm, 1 μm, 5 μm, 10 μm, 20 μm, 30 μm, 40 μm, or 50 μm, where any value can be a lower and upper endpoint of a range (e.g., 10 μm to 30 μm).

The selection of the pulsed laser can vary depending upon the amount of desired microtexturizing as well as the material of the target substrate to be microtexturized. By modifying the pulsed laser parameters as discussed below, the dimensions of the features produced on the microtexturized substrate can be modified.

In one aspect, the pulsed laser has a wavelength range of about 250 nm to about 11,000 nm.

In one aspect, the pulsed laser is an ultraviolet laser. In one aspect, the ultraviolet laser has a wavelength of from about 250 nm to about 450 nm, or about 250 nm, 275 nm, 300 nm, 325 nm, 350 nm, 375 nm, 400 nm, 425 nm, or 450 nm, where any value can be a lower and upper endpoint of a range (e.g., 325 nm to 400 nm).

In another aspect, the pulsed laser is an infra-red laser. In one aspect, the infra-red laser has a wavelength of from about 900 nm to about 1,100 nm, or about 900 nm, 925 nm, 950 nm, 975 nm, 1,000 nm, 1,025 nm, 1,050 nm, 1075 nm, or 1,100 nm, where any value can be a lower and upper endpoint of a range (e.g., 1,000 nm to 1,100 nm). In another aspect, the infrared laser has a wavelength of about 1,064 nm.

In one aspect, the pulsed laser has a wavelength of from about 400 nm to about 600 nm, or about 400 nm, 425 nm, 450 nm, 475 nm, 500 nm, 525 nm, 550 nm, 575 nm, or 600 nm, where any value can be a lower and upper endpoint of a range (e.g., 525 nm to 550 nm). In another aspect, the laser is produced by an ytterbium fiber laser.

Depending upon the selection of the pulsed laser, the power of the laser can vary. In one aspect, the pulsed laser is applied at from about 20% laser power to about 80% laser power, or about 20%, 25%, 30%, 35%, 40%, 45%, 50%, 55%, 60%, 65%, 70%, 75%, or 80%, where any value can be a lower and upper endpoint of a range (e.g., 30% to 50%). In another aspect, the laser is applied at a power of from about 1 W to about 1,000 W, or about 1W, 10 W, 20 W, 30 W, 40 W, 50 W, 60 W, 70 W, 80 W, 90 W, 100 W, 200 W, 300 W, 400 W, 500 W, 600 W, 700 W, 800 W, 900 W, or 1,000 W, where any value can be a lower and upper endpoint of a range (e.g., 20 W to 40 W).

In another aspect, the pulsed laser has a frequency of about 1 Hz to about 100 MHz, or about 1 kHz, 10 kHz, 20 kHz, 30 kHz, 40 kHz, 50 kHz, 60 kHz, 70 kHz, 80 kHz, 90 kHz, 100 kHz, 200 kHz, 300 kHz, 400 kHz, 500 kHz, 600 kHz, 700 kHz, 800 kHz, 900 kHz, or 1,000 kHz, where any value can be a lower and upper endpoint of a range (e.g., 1 Hz to 100 MHz).

In another aspect, the pulsed laser has a pulse energy of from about 1 μJ to about 100 J, or 1 μJ, 0.1 J, 0.5 J, 1.0 J, 5 J, 10 J, 20 J, 30 J, 40 J, 50 J, 60 J, 70 J, 80 J, 90 J, or 100 J, where any value can be a lower and upper endpoint of a range (e.g., 0.5 J to 5 J).

In other aspects, the diameter of the pulsed laser can be modified. In one aspect, the pulsed laser has a beam size of from about 1 μm to about 100 μm, or 1 μm, 5 μm, 10 μm, 20 μm, 30 μm, 40 μm, 50 μm, 60 μm, 70 μm, 80 μm, 90 μm, 100 μm, 1 mm, 10 mm, 50 mm, or 100 mm, where any value can be a lower and upper endpoint of a range (e.g., 10 μm to 30 μm).

In another aspect, the pulsed laser is applied to the target substrate at a scan speed of from about 0.1 mm/s to about 10,000 mm/s, or about 0.1 mm/s, 10 mm/s, 50 mm/s, 100 mm/s, 200 mm/s, 300 mm/s, 400 mm/s, 500 mm/s, 600 mm/s, 700 mm/s, 800 mm/s, 900 mm/s, 1,000 mm/s, 2,000 mm/s, 3,000 mm/s, 4,000 mm/s, 5,000 mm/s, 6,000 mm/s, 7,000 mm/s, 8,000 mm/s, 9,000 mm/s, or 10,000 mm/s, where any value can be a lower and upper endpoint of a range (e.g., 400 mm/s to 600 mm/s).

An exemplary schematic for producing microtexturized surfaces using the methods described herein is provided in FIG. 13. Referring to FIG. 13, a microtexturizing laser 10 produced from laser device 20 is directed onto target substrate 50. The microtexturizing laser beam 10 is applied to the target substrate with bound metal using a galvanometer 30 to specifically target or direct the laser 40 to a specific cite on the target substrate 50. In one aspect, during microtexturizing with the microtexturizing laser, air or an inert gas such as nitrogen or argon can be blown on the target substrate while the target substrate is subjected to the microtexturizing laser. In one aspect, the pulsed laser is mounted on translation stage. Here, the pulsed laser can be moved in any direction (i.e., x- or y-axis) relative to the target substrate to microtexturize specific regions of the substrate.

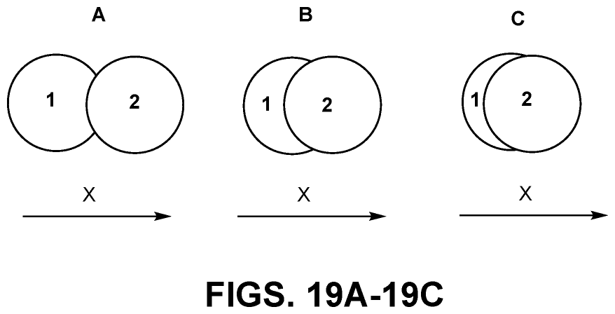

The first surface of the target substrate is subjected to a plurality of pulsed lasers (i.e., the substrate surface is exposed multiple laser beams). Depending upon the amount of texturizing and feature dimensions to be produced on the substrate surface, the spacing of each laser beam relative to one another can vary. This is referred to herein as “controlled overlap of each pulsed laser.” For example, the substrate surface can be subjected to two laser beams that each produce a laser spot on the substrate surface. Depending upon the positioning of each laser beam, the laser spots overlap or, in the alternative, there is no overlap. In one aspect, the overlap between each laser (i.e., laser spot) along a direction of scanning is from about 0% to about 99.5%, or 0%, 5%, 10%, 20%, 30%, 40%, 50%, 60%, 70%, 80%, 90%, or 99.5%, where any value can be a lower and upper endpoint of a range (e.g., 40% to 60%). FIGS. 19A-19C show the cross-sectional overlap of two pulsed laser beams 1 and 2 at different percentages of overlap along a direction of scanning of the pulsed laser (depicted as X).

Exemplary methods for surface treating (e.g., microtexturizing and/or plasma treatment) the target substrate prior to depositing the hydrophobic material are provided in the Examples. In one aspect, the first surface of the target us microtexturized followed by plasma treatment.

In certain aspects, the first surface of the target substrate to be microtexturized and be pre-treated prior to being microtexturized. In one aspect, the first surface of the target substrate is polished to a surface roughness of less than 1 μm prior to subjecting the surface of the substrate to the pulsed laser. In another aspect, the first surface of the target substrate is abraded to roughness of from about 0.01 μm to about 20 μm prior to microtexturizing. For example, the first surface can be abraded with sandpaper.

In another aspect, the microtexturized target substrate can be subsequently surface treated with a high-energy discharge treatment to modify the surface energy, for example a flame treatment, a corona treatment, a plasma treatment, or a combination thereof prior to laser deposition of the hydrophobic material as discussed above.

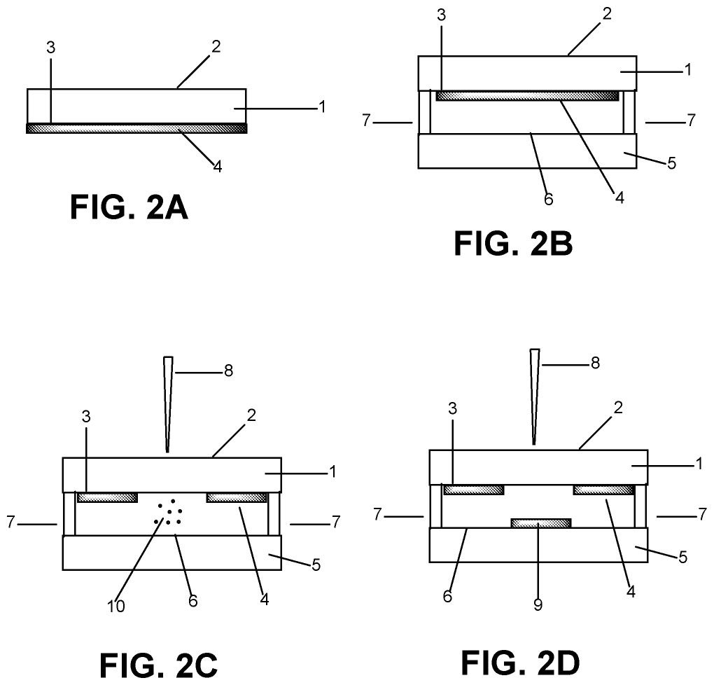

FIGS. 2A-2D show a schematic representation for producing the superhydrophobic substrates described herein. Referring to FIG. 2A, a coating of hydrophobic material 4 is applied to the second surface 3 of the first glass substrate 1 having a first surface 2 and a second surface 3. The hydrophobic material can be applied to the second surface of the first glass substrate using techniques known in the art including, but not limited, pouring, dipping, spraying, and the like. The amount and thickness of the hydrophobic material applied to the second surface of the first glass substrate can vary depending upon the amount material to be deposited on the target substrate.

The first glass substrate 1 can be composed of any material that is optically transparent so that the depositing laser can transmit through the first substrate and contact the hydrophobic material that is present on the second surface of the first glass substrate. In one aspect, the first glass substrate is composed of borosilicate, fused silica, sapphire, or any combination thereof.

The methods described herein are useful in laser depositing a variety of different hydrophobic materials on a target surface. In one aspect, the hydrophobic material comprises a polyolefin (e.g., homo- and copolymers of ethylene or propylene) or a fluorinated polymer (polytetrafluoroethylene (PTFE), polyethylene, or a fluorinated ethylene propylene (FEP)). In another aspect, the hydrophobic material is a polysiloxane. Polysiloxanes are materials composed of a plurality of —Si—O—Si— linkages.

In one aspect, the hydrophobic material is a dialkylpolysiloxane having the repeat units

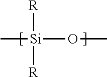

where each R is an alkyl group. In one aspect, each alkyl group is the same alkyl group. In another each alkyl group is a C1 to C10 branched alkyl group such as, for example, methyl, ethyl, butyl, and the like. In another aspect, the hydrophobic material is polydimethylsiloxane (PDMS).

In certain aspect, the hydrophobic material further comprises a curing agent. In one aspect, the hydrophobic material and the curing agent composition are a mixture in a ratio of from 5:1 ratio (v/v) to 15:1 (v/v). In one aspect, after the hydrophobic material has been applied to the second surface of the first glass substrate, the coating of hydrophobic material is heated at a temperature of from about 75° C. to about 125° C., or about 75° C., 80° C., 85° C., 90° C., 95° C., 100° C., 105° C., 110° C., 115° C., 120° C., or 125° C., where any value can be a lower and upper endpoint of a range (e.g., 95° C. to 110° C.). Not wishing to be bound by theory, the heating step partially cures the hydrophobic material. Exemplary methods for applying the hydrophobic material to the second surface of the first glass substrate and performing optional steps such as heating are provided in the Examples.

Referring to FIG. 2B, the second surface 3 of the first glass substrate 1 with the coating of hydrophobic material 4 is positioned in proximity to the first surface 6 of the target substrate 5. The coating of hydrophobic material 4 is not in contact with the first surface of a target substrate. In one aspect, one or more spacers are positioned between the second surface of the first glass substrate and the first surface of the target substrate. This aspect is depicted in FIG. 2B, where spacers 7 create a gap between the hydrophobic coating 4 and the first surface 6 of the target substrate 5. In one aspect, the second surface of the first glass substrate is from about 10 μm to about 10 mm to the first surface of the target substrate, or about 10 μm, 50 μm, 100 μm, 200 μm, 300 μm, 400 μm, 500 μm, 600 μm, 700 μm, 800 μm, 900 μm, 1,000 μm, 1 mm, 2 mm, 3 mm, 4 mm, 5 mm, 6 mm, 7 mm, 8 mm, 9 mm, or 10 mm, where any value can be a lower and upper endpoint of a range (e.g., 100 μm to 2 mm).

Referring to FIGS. 2C and 2D, a depositing laser 8 is applied to the first surface 2 of the first glass substrate 1, wherein the hydrophobic material 4 on the second surface 3 of the first glass substrate 1 is converted to hydrophobic particles 10 and deposited on the first surface of the target substrate to produce a hydrophobic coating 9 on the first surface 6 of the target substrate 5.

The selection of the depositing laser can vary. In one aspect, the depositing laser is an ultraviolet laser. In one aspect, the ultraviolet laser has a wavelength of from about 250 nm to about 450 nm, or about 250 nm, 275 nm, 300 nm, 325 nm, 350 nm, 375 nm, 400 nm, 425 nm, or 450 nm, where any value can be a lower and upper endpoint of a range (e.g., 325 nm to 400 nm). In another aspect, the ultraviolet laser has a wavelength of about 355 nm.

In another aspect, the depositing laser is an infra-red laser. In one aspect, the infra-red laser has a wavelength of from about 900 nm to about 1,100 nm, or about 900 nm, 925 nm, 950 nm, 975 nm, 1,000 nm, 1,025 nm, 1,050 nm, 1075 nm, or 1,100 nm, where any value can be a lower and upper endpoint of a range (e.g., 1,000 nm to 1,100 nm). In another aspect, the infrared laser has a wavelength of about 1,064 nm.

In one aspect, the depositing laser has a wavelength of from about 400 nm to about 600 nm, or about 400 nm, 425 nm, 450 nm, 475 nm, 500 nm, 525 nm, 550 nm, 575 nm, or 600 nm, where any value can be a lower and upper endpoint of a range (e.g., 525 nm to 550 nm). In another aspect, the depositing laser is produced by an ytterbium fiber laser.

Depending upon the selection of the depositing laser, the power of the laser can vary. In one aspect, the depositing laser is applied at from about 20% laser power to about 80% laser power, or about 20%, 25%, 30%, 35%, 40%, 45%, 50%, 55%, 60%, 65%, 70%, 75%, or 80%, where any value can be a lower and upper endpoint of a range (e.g., 30% to 50%). In another aspect, the depositing laser is applied at a power of from about 1 W to about 1,000 W, or about 1W, 10 W, 20 W, 30 W, 40 W, 50 W, 60 W, 70 W, 80 W, 90 W, 100 W, 200 W, 300 W, 400 W, 500 W, 600 W, 700 W, 800 W, 900 W, or 1,000 W, where any value can be a lower and upper endpoint of a range (e.g., 20 W to 40 W).

In another aspect, the depositing laser has a frequency of about 1 Hz to about 100 MHz, or about 1 kHz, 10 kHz, 20 kHz, 30 kHz, 40 kHz, 50 kHz, 60 kHz, 70 kHz, 80 kHz, 90 kHz, 100 kHz, 200 kHz, 300 kHz, 400 kHz, 500 kHz, 600 kHz, 700 kHz, 800 kHz, 900 kHz, or 1,000 kHz, where any value can be a lower and upper endpoint of a range (e.g., 1 Hz to 100 MHz).

In another aspect, the depositing laser has a pulse energy of from about 1 μJ to about 100 J, or 1 μJ, 0.1 J, 0.5 J, 1.0 J, 5 J, 10 J, 20 J, 30 J, 40 J, 50 J, 60 J, 70 J, 80 J, 90 J, or 100 J, where any value can be a lower and upper endpoint of a range (e.g., 0.5 J to 5 J).

In other aspects, the width of the depositing laser can be modified. In one aspect, the laser has a beam size of from about 1 μm to about 10,000 μm, or 1 μm, 5 μm, 10 μm, 20 μm, 30 μm, 40 μm, 50 μm, 60 μm, 70 μm, 80 μm, 90 μm, 100 μm, 100 μm, 1,000 μm, 2,000 μm, 4,000 μm, 6,000 μm, 8,000 μm, or 10,000 μm, where any value can be a lower and upper endpoint of a range (e.g., 10 μm to 30 μm).

In another aspect, the depositing laser is applied to the first glass substrate at a scan speed of from about 1 mm/s to about 1,000 mm/s, or about 1 mm/s, 10 mm/s, 50 mm/s, 100 mm/s, 200 mm/s, 300 mm/s, 400 mm/s, 500 mm/s, 600 mm/s, 700 mm/s, 800 mm/s, 900 mm/s, or 1,000 mm/s, where any value can be a lower and upper endpoint of a range (e.g., 400 mm/s to 600 mm/s).

In one aspect, the depositing laser is applied to the first surface of the first glass substrate at a line spacing of about 1 μm to about 10,000 μm, or 1 μm, 5 μm, 10 μm, 20 μm, 30 μm, 40 μm, 50 μm, 60 μm, 70 μm, 80 μm, 90 μm, 100 μm, 100 μm, 1,000 μm, 2,000 μm, 4,000 μm, 6,000 μm, 8,000 μm, or 10,000 μm, where any value can be a lower and upper endpoint of a range (e.g., 10 μm to 30 μm).

In one aspect, during the deposition of the hydrophobic material to the first surface of the target substrate, air or an inert gas such as nitrogen or argon can be blown on the target substrate while the hydrophobic particles are deposited on the first surface of the target substrate.

The size of the of the hydrophobic particles deposited on the target substrate can vary. In one aspect, the hydrophobic particles have an average size of from about 1 nm to about 10 μm, 1 nm, 10 nm, 100 nm, 200 nm, 300 nm, 400 nm, 500 nm, 600 nm, 700 nm, 800 nm, 900 nm, 1,000 nm, 1 μm, 2 μm, 3 μm, 4 μm, 5 μm, 6 μm, 7 μm, 8 μm, 9 μm, or 10 μm, where any value can be a lower and upper endpoint of a range (e.g., 200 nm to 2 μm).

The thickness of the of the hydrophobic coating deposited on the target substrate can vary. In one aspect, the hydrophobic coating has a thickness of from about 1 nm to about 10 μm, 1 nm, 10 nm, 100 nm, 200 nm, 300 nm, 400 nm, 500 nm, 600 nm, 700 nm, 800 nm, 900 nm, 1,000 nm, 1 μm, 2 μm, 3 μm, 4 μm, 5 μm, 6 μm, 7 μm, 8 μm, 9 μm, or 10 μm, where any value can be a lower and upper endpoint of a range (e.g., 200 nm to 2 μm).

In one aspect, after the hydrophobic particles have been deposited on the first surface of the first glass substrate, the coating of hydrophobic particles is heated at a temperature of from about 25° C. to about 250° C., or about 25° C., 50° C., 75° C., 100° C., 125° C., 150° C., 175° C., 200° C., 225° C., or 250° C., where any value can be a lower and upper endpoint of a range (e.g., 75° C. to 125° C.).

In one aspect, the hydrophobic particles can be selectively deposited on the first surface of the target substrate in a patterned formation. In one aspect, the depositing laser can be applied to the first glass substrate using a galvanometer to specifically target or direct the depositing laser to a specific cite on the first glass substrate. This in turn will produce hydrophobic particles that will be deposited on the first surface of the target substrate in a patterned formation. In one aspect, the patterned surface is a microscale patterned surface comprising one or more lines of hydrophobic particles on the first surface of the target substrate. In one aspect, the lines have a thickness of from about 0.1 μm to about 1,000 μm. In another aspect, the lines have a width of from about 1 μm to about 10,000 μm.

The methods described herein produce articles and substrates that possess superhydrophobic properties. Moreover, the degree or amount of hydrophobicity can be modified depending upon the application of the coated article. For example, if the target substrate is microtexturized prior to producing the hydrophobic coating, the degree of hydrophobicity can be increased. In one aspect, the substrates with hydrophobic coatings produced herein have a water contact angle of from about 130° to about 175°, or 130°, 135°, 140°, 145°, 150°, 155°, 155°, 160°, 165°, 170°, or 175°, where any value can be a lower and upper endpoint of a range (e.g., 150° to 170°). In another aspect, the substrates with hydrophobic coatings produced herein have a roll off angle of at least about 1° to about 10°, or about 1°, 2°, 3°, 4°, 5°, 6°, 7°, 8°, 9°, or 10°, where any value can be a lower and upper endpoint of a range (e.g., 2° to 8°). In another aspect, the substrates with hydrophobic coatings produced herein have a contact angle hysteresis of less than 10°, less than 7°, or less than 5°. Techniques for determining the water contact angle and roll off angle of the superhydrophobic substrates produced herein are provided in the Examples.

The hydrophobic coatings produced herein have good adhesion to the target substrate, which makes the coatings durable particularly when exposed to harsh or extreme conditions. In general, the adhesion of hydrophobic materials such as polysiloxanes to substrate is weak. The methods described here in produce hydrophobic coatings with strong adhesion to the target substrate. In one aspect, the hydrophobic particles adhere to the target substrate with a peel strength of at least about 1 N/cm², at least about 5 N/cm², at least about 10 N/cm², at least about 15 N/cm², or at least about 20 N/cm². Techniques for determining the peel strength of the superhydrophobic coatings produced herein are provided in the Examples.

In one aspect, the target substrate is optically transparent or non-transparent. In another aspect, when the target substrate comprises a glass, the coated glass produced by the methods described herein can efficiently transmit light. In one aspect, the target substrate optically transmits at least 75%, at least 80%, at least 85%, or at least 90% of light reaching the surface.

The methods described herein produce superhydrophobic surfaces and substrates that have numerous commercial and industrial applications. Superhydrophobic surfaces have important applications in generating anti-icing properties, preventing corrosion, producing anti-biofouling characteristics, and microfluidic devices. In one aspect, the superhydrophobic surfaces and substrates produced herein can be incorporated in or are a component of a battery, a textile, a solar panel, a medical device, an aircraft, construction equipment, a microfluidic device, aircrafts, boats and ships, submarines, wind turbines, or any combination thereof. In another aspect, when the hydrophobic particles are produced in a patterned formation, the resulting patterned coated substrate can be used as microfluidic microchannels and other optical devices.

In certain aspects and applications, it is desirable to remove some or all the hydrophobic coating produced herein. For example, removing some or all the hydrophobic coating can be used to modify the hydrophobic properties of the target substrate. In one aspect, when the target substrate has been microtexturized as described herein prior to applying the hydrophobic coating, the microtexturized substrate is very hydrophilic. Thus, it is possible to revert back to hydrophilic/hydrophobic substrates by removing the hydrophobic coating. Removal of the hydrophobic coating can be accomplished by techniques such as, for example, peeling or abrading the hydrophobic coating from the substrate.

### Aspects

Aspect 1. A method for producing a superhydrophobic surface on an article, the method comprising laser depositing hydrophobic materials on at least one surface of the article.

Aspect 2. The method of Aspect 1, wherein the method comprises
(a) applying a coating of the hydrophobic material on a second surface of a first glass substrate having a first surface and a second surface;
(b) positioning the second surface of the first glass substrate in proximity to a first surface of a target substrate; and
(c) applying a depositing laser to the first surface of the first glass substrate, wherein the hydrophobic material on the second surface of the first glass substrate are converted to hydrophobic particles and deposited on the first surface of the target substrate.

Aspect 3. The method of Aspect 1 or 2, wherein the hydrophobic material comprises a polysiloxane, a polyolefin, or a fluorinated polymer.

Aspect 4. The method of Aspect 1 or 2, wherein the hydrophobic material comprises polytetrafluoroethylene (PTFE), polyethylene, or a fluorinated ethylene propylene (FEP).

Aspect 5. The method of Aspect 1 or 2, wherein the hydrophobic material comprises a dialkylpolysiloxane.

Aspect 6. The method of Aspect 1 or 2, wherein the hydrophobic material comprises polydimethylsiloxane (PDMS).

Aspect 7. The method of any one of Aspects 2-6, wherein the hydrophobic material further comprises a curing agent.

Aspect 8. The method of Aspect 7, wherein the hydrophobic material and the curing agent composition are a mixture in a ratio of from 5:1 ratio (v/v) to 15:1 (v/v).

Aspect 9. The method of any one of Aspects 2-8, wherein the coating of the hydrophobic material has a thickness of from about 0.1 μm to about 1,000 μm.

Aspect 10. The method of any one of Aspects 2-9, wherein prior to step (a), microtexturizing the first surface of the target substrate.

Aspect 11. The method of Aspect 10, wherein the first surface of the target substrate is subjected to a pulsed laser across the first surface at a controlled overlap of each pulsed laser to produce the microtextured surface.

Aspect 12. The method of Aspect 11, wherein the pulsed laser has a wavelength range of about 250 nm to about 11,000 nm.

Aspect 13. The method of Aspect 11, wherein the pulsed laser has an average power of about 1W to about 1,000 W.

Aspect 14. The method of Aspect 11, wherein the pulsed laser has a pulse frequency range of about 1 Hz to about 100 MHz.

Aspect 15. The method of Aspect 11, wherein the pulsed laser has a pulse energy of from about 1 μJ to about 100 J.

Aspect 16. The method of Aspect 11, wherein the pulsed laser has a diameter in the range of about 1 μm to about 100 mm.

Aspect 17. The method of Aspect 11, wherein the first surface of the target substrate is subjected to the pulsed laser at a scanning rate of from about 0.1 mm/s to about 10,000 mm/s.

Aspect 18. The method of Aspect 11, wherein the overlap between each pulsed laser along a direction of scanning is from about 0% to about 99.5%.

Aspect 19. The method of any one of Aspects 2-18, wherein prior to step (c), the first surface of the target substrate is treated with a high-energy discharge treatment comprising a flame treatment, a corona treatment, a plasma treatment, or a combination thereof.

Aspect 20. The method of any one of Aspects 2-19, wherein prior to step (b), the coating of hydrophobic material is heated at a temperature of from about 75° C. to about 125° C.

Aspect 21. The method of any one of Aspects 2-20, wherein the first glass substrate comprises borosilicate, fused silica or sapphire.

Aspect 22. The method of any one of Aspects 2-21, wherein in step (b), the second surface of the first glass substrate is from about 10 μm to about 10 mm to the first surface of the target substrate.

Aspect 23. The method of any one of Aspects 2-22, wherein in step (b), one or more spacers are positioned between the second surface of the first glass substrate and the first surface of the target substrate.

Aspect 24. The method of any one of Aspects 2-23, wherein the depositing laser is an ultraviolet laser.

Aspect 25. The method of any one of Aspects 2-23, wherein the depositing laser is an infra-red laser.

Aspect 26. The method of any one of Aspects 2-23, wherein the depositing laser is applied to the first surface of the first glass substrate at a scan speed of from about 1 mm/s to about 1000 mm/s.

Aspect 27. The method of any one of Aspects 2-23, wherein the depositing laser has an average power of from about 1 W to about 100 W.

Aspect 28. The method of any one of Aspects 2-23, wherein the depositing laser has a beam size of from about 1 μm to about 10,000 μm.

Aspect 29. The method of any one of Aspects 2-23, wherein the depositing laser has a frequency of about 1 Hz to about 100 MHz.

Aspect 30. The method of any one of Aspects 2-23, wherein the depositing laser has a pulse energy of from about 1 μJ to about 100 J.

Aspect 31. The method of any one of Aspects 2-23, wherein the depositing laser is applied to the first surface of the first glass substrate at a line spacing of about 1 μm to about 10,000 μm.

Aspect 32. The method of any one of Aspects 2-31, further comprising blowing an inert gas on the coating of the hydrophobic material during step (c).

Aspect 33. The method of Aspect 32, wherein the gas comprises nitrogen, argon, air, oxygen or a combination thereof.

Aspect 34. The method of any one of Aspects 2-33, wherein after step (c), curing the hydrophobic particles deposited on the first surface of the target.

Aspect 35. The method of any one of Aspects 2-33, wherein after step (c), heating the hydrophobic particles deposited on the first surface of the target substrate at a temperature of from about 25° C. to about 250° C.

Aspect 36. The method of any one of Aspects 2-35, wherein the hydrophobic particles are deposited on the target substrate in a layer having a thickness of from about 1 nm to about 10 μm thick.

Aspect 37. The method of any one of Aspects 2-36, wherein the hydrophobic particles have an average size of from about 1 nm to about 10 μm.

Aspect 38. The method of any one of Aspects 2-37, wherein the hydrophobic particles are deposited on the first surface of the target substrate in a patterned formation.

Aspect 39. The method of any one of Aspects 2-38, wherein the target substrate comprises glass, aluminum, metals, polymers, ceramics, composites, alloys or any combination thereof.

Aspect 40. A superhydrophobic article made by the method of any one of Aspects 1-39.

Aspect 41. The hydrophobic article of Aspect 40, wherein when the target substrate is optically transparent.

Aspect 42. The superhydrophobic article of Aspect 40, wherein when the target substrate comprises a glass.

Aspect 43. The superhydrophobic article of Aspect 41 or 42, wherein the target substrate is optically transparent or non-transparent.

Aspect 44. The superhydrophobic article of any one of Aspects 40-43, wherein the superhydrophobic article has a water contact angle between about 130° to about 175°.

Aspect 45. The superhydrophobic article of any one of Aspects 40-44, wherein the superhydrophobic article has a roll off angle of at least about 1° to about 10°.

Aspect 46. The superhydrophobic article of any one of Aspects 40-45, wherein the superhydrophobic particles adhere to the substrate with a peel strength greater than 1 N/cm².

Aspect 47. The superhydrophobic article of any one of Aspects 40-46, wherein the article comprises a battery, a textile, a solar panel, a medical device, an aircraft, construction equipment, a microfluidic device, aircrafts, boats and ships, submarines, wind turbines, or any combination thereof.

Aspect 48. The superhydrophobic article of any one of Aspects 40-47, wherein the hydrophobic particles are selectively deposited on the surface of the article to create a patterned surface.

Aspect 49. The superhydrophobic article of Aspect 48, wherein the patterned surface is a microscale patterned surface comprising one or more lines of hydrophobic or superhydrophobic particles.

Aspect 50. The superhydrophobic article of Aspect 49, wherein the lines have a thickness of from about 0.1 μm to about 1,000 μm.

Aspect 51. The superhydrophobic article of Aspect 48 or 50, wherein the lines have a width of from about 1 μm to about 10,000 μm.

Now having described the aspects of the present disclosure, in general, the following Examples describe some additional aspects of the present disclosure. While aspects of the present disclosure are described in connection with the following examples and the corresponding text and figures, there is no intent to limit aspects of the present disclosure to this description. On the contrary, the intent is to cover all alternatives, modifications, and equivalents included within the spirit and scope of the present disclosure.

### Examples

The following examples are put forth so as to provide those of ordinary skill in the art with a complete disclosure and description of how the compounds, compositions, articles, devices and/or methods claimed herein are made and evaluated and are intended to be purely exemplary of the disclosure and are not intended to limit the scope of what the inventors regard as their disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

### Example 1: Experimental

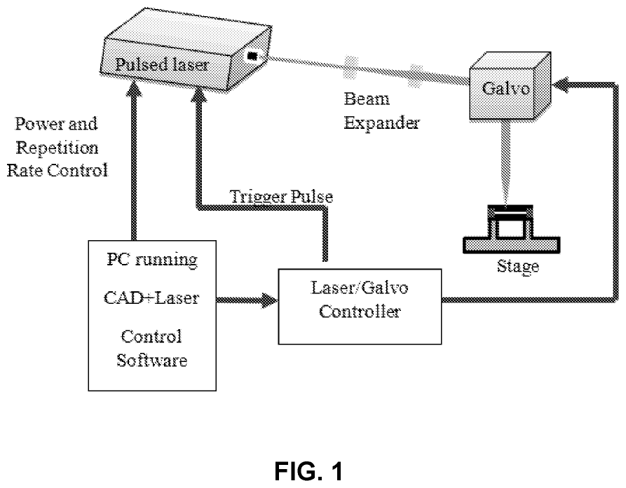

A schematic diagram of the laser microtexturing setup has been shown in FIG. 1. The 355 nm wavelength Coherent Matrix 355-8-50 nanosecond pulsed laser was used to ablate PDMS and deposit it onto the desired substrate, as shown in FIGS. 2A-2B. The Polydimethylsiloxane (PDMS) that was used was SYLGARD 184 Silicon Elastomer which is a two-part solution mixture. Ten parts of polymer and 1 part of the curing agent were mixed thoroughly and placed in a vacuum desiccator to eliminate air pockets introduced during the mixing process. After eliminating the air bubbles, the PDMS solution was poured onto plasma-treated borosilicate glass slides (length=3 inches, width=1 inch, and thickness=0.04 inches; purchased from Amscope). The thickness of the layer is roughly around 100 μm. The plasma treatment of glass allows for achieving an increased bond between the PDMS and glass. The PDMS deposited glass slide was subjected to a temperature of 100° C. to semi-cure the PDMS. Semi-curing the PDMS helps the laser-ablated PDMS particles to adhere better to the target substrate. Thereafter, the laser was used to ablate the semi-cured PDMS and deposit it on the target substrate. In the present case, aluminum and glass substrates were used. After the deposition of the PDMS, the PDMS coated glass/aluminum substrates were cured for an additional 10 min. at 100° C.

The aluminum alloy (McMaster-Carr Al 7075) samples of 1-inch length, 1-inch width, and 0.07-inch thickness were polished down to a roughness of less than 1 μm. The PMMA samples of 4 mm thickness, 1-inch width, and 1-inch length were purchased from Ding&ng. The chemical composition of Al 7075 by weight was Al=89.77%, Zn=5.4%, Cu=1.42%, Mn=0.12%, Mg=2.42%, Fe=0.42%, Cr=0.21%, Ti=0.11%, and Si=0.13%.

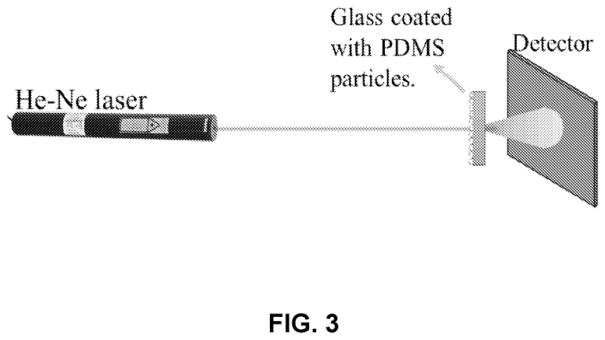

The contact angle measurements were done using the Ram6-Hart model 250 Goniometer. The optical transmission through the transferred particles formed a coating on glass was measured using a 5 mW He—Ne laser of 632 nm wavelength and Thorlabs S302C thermal power sensor, as shown in FIG. 3. The adhesion of the nano/micro particles was tested by scotch tape test. The scotch tape used has ˜20 N/cm² adhesion strength and was tested five times.

### Sample Preparation

The PDMS that was used in this experiment was a two-part solution mixture. Ten parts of the polymer and 1 part of the curing agent were mixed thoroughly and placed in a vacuum desiccator for 30 minutes to eliminate air pockets introduced during the mixing process. After eliminating the air bubbles, the PDMS solution was carefully poured and spread onto a microscope glass slide. The thickness of the PDMS layer was roughly 100-120 μm. The thickness was attained by placing cover glasses of 100-120 μm thickness around the edges of the top face of the glass slide and ensuring that the poured PDMS forms a smooth coverage by scraping off any excess PDMS off the top using a thin blade. Keeping a relatively low PDMS thickness makes it easier for the laser light to be able to focus on the surface of the cured PDMS without undergoing significant absorption or scattering in the bulk of the PDMS layer. It also provides better control of the laser spot over the selected scan area. The poured PDMS on the glass slide was subjected to a temperature of 100° C. for 25 min on a hot plate to partially cure the PDMS. Two other glass slides with poured PDMS were prepared using the same process, and they were cured for 15 and 20 minutes, respectively. This was done to study the effect of different curing times on the laser ablation process. The thickness of the poured PDMS on these glass slides was also maintained at 100-120 μm. The glass slides and the aluminum on which the ablated PDMS micro/nanoparticles are to be deposited were treated with plasma (Jelight Company UVO-Cleaner Model 18) for 10 min.

### Laser Ablation Procedure

A 355 nm wavelength nanosecond pulsed laser was used to ablate the PDMS coating made on a glass slide. The 355 nm wavelength 20 nanoseconds pulsed width laser from Coherent Matrix 355-8-50, operated at 50 kHz pulse repetition rate, at 8 W average power, was used in this study as shown in FIG. S1. High Dynamics PIMag linear XY stages were used for mounting the samples, and the laser beam was scanned using the Sino-Galvo SG7210 system.

The 355 nm wavelength laser was chosen because the absorption of light by PDMS is higher in the UV spectrum. The UV nanosecond pulsed laser was used to ablate the deposited PDMS on glass, and the ablated material was transferred onto the target substrate through evaporation of the ablated PDMS fragments. The experimental setup of this experiment is shown in FIG. 1b. Aluminum and glass were used as substrates. After the formation of the ablated PDMS micro/nanoparticles coating on the substrate, the substrates were heated for an additional 10 min. at 100° C. to ensure good bonding and to fully cure the PDMS.

### Abrasion Testing Procedure

A shear (abrasion) test was performed using a micro tribometer (CETR Inc., CA, USA). FIG. S2 shows a schematic of the shear test setup. A tool steel blade with a dimension of 3×2.4 ×7 mm was attached to a 1000 N load cell. The cell can record both normal and lateral forces. During the shear test, the glass substrate with the laser-ablated PDMS micro/nanoparticles coating was first glued onto the sample stage of the micro tribometer. Then the steel blade was brought into contact with the substrate under a 2 N normal force Fₙ, which keeps the blade in good contact with the substrate surface. The sample was moved laterally at a speed of 0.5 mm/s towards the steel blade. Once the steel blade came in contact with the coating, a shear force (Fs) was applied to the coating. The variation of the lateral shear force was recorded as a function of time until the coating was completely scraped off. The nominal ultimate shear strength T_{Max} can be defined by equation 1:

$${τ}_{Max} = \frac{{F}_{S , Max}}{{A}_{Int}} \qquad ( 1 )$$

where F_{S,Max} is the maximum shear force during the shear test, and Aᵢₙₜ is the interfacial contact area of the coating. An acoustic emission (AE) signal was also collected by the AE sensor attached to the substrate to monitor the process of scraping the coating off of the surface.

### Surface Characterization

The surface morphology analysis of the laser-ablated PDMS micro/nanoparticles was done by using FEI Quanta 650 Field Emission Microscope, and chemical composition was done by XPS (PHI Versaprobe Ill). The abrasion resistance of the surface was determined by using the CETR micro tribometer. The water contact angle measurements were done using the Ram6-Hart Model 250 Goniometer.

### Optical Characterization

Optical transmission measurements were obtained using a UV-VIS-NIR spectrophotometer (Agilent CARY 5000) with a tungsten halogen visible and deuterium arc UV light source and a silicon photodiode receiver. The wavelength range for the scan was from 200 nm to 1100 nm to ensure complete coverage of the UV and visible spectrum and some of the near IR spectrum as well. The measurements were done on different areas of a UV fused silica window (Thorlabs WG41010R), poured, and partially cured PDMS on silica and PDMS micro/nanoparticles deposited silica surface to ensure repeatability and minimize variability.

### Example 2: Preliminary Results

PDMS Nano.Micro Particle Transfer onto Glass and Aluminum Surfaces

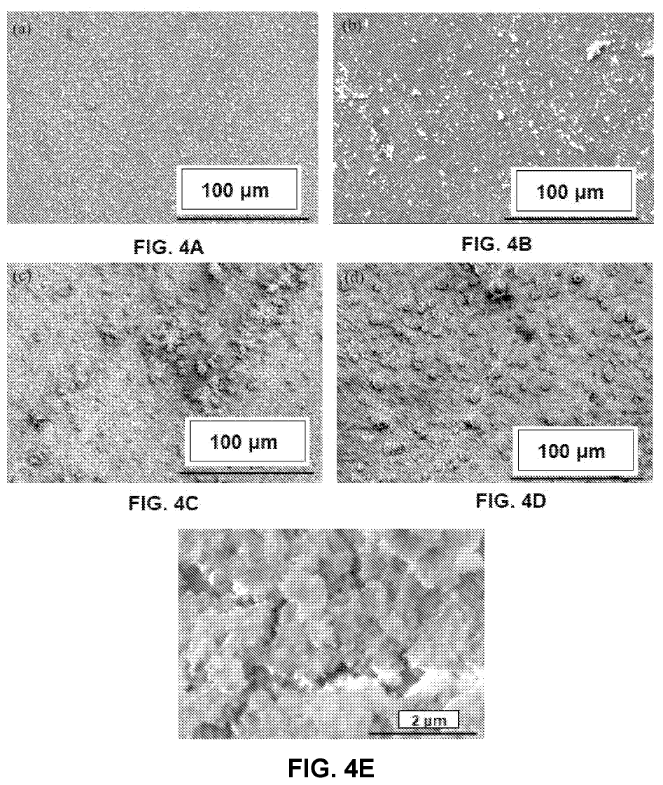

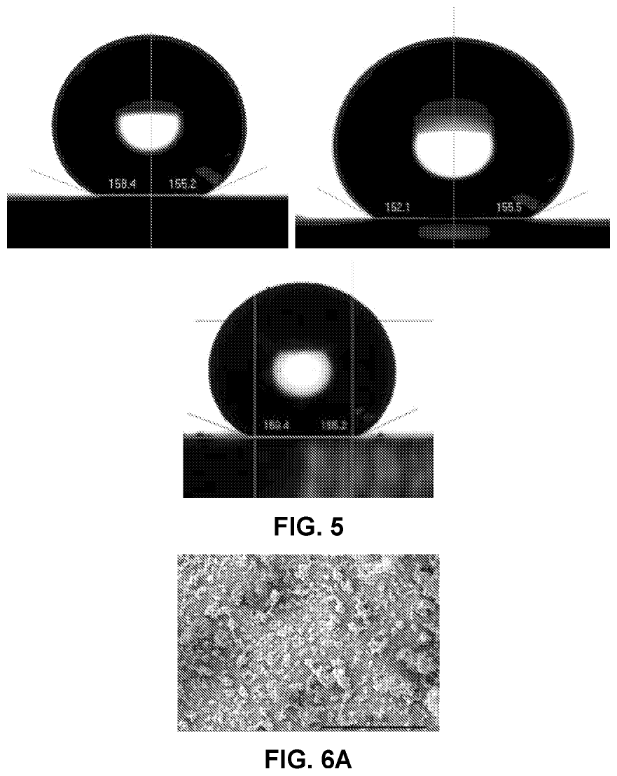

Different settings of laser parameters were tested for the laser ablation process to find out the optimal condition to achieve superhydrophobic surfaces. It was found that scan speeds of above 200 mm/s make the laser beam move too fast and do not ablate enough PDMS per unit area to create a superhydrophobic surface on the substrate. Hence, the laser speed was chosen to be 200 mm/s. The laser fluences were varied across a range of 1.1-2.3 mJ/cm², keeping the scan speed constant at 200 mm/s. FIGS. 4A-4E show the effect of varying fluences on the deposited PDMS micro/nanoparticles on the glass substrate. It was observed that at higher fluences, more PDMS particles get ablated and deposited on the substrate. It is necessary to have a certain number of PDMS micro/nanoparticles on the substrate in order to achieve superhydrophobicity. The substrate surface starts to show superhydrophobicity above 2.2 mJ/cm². The side-to-side line-spacing and the frequency of the laser were kept at 20 μm and 50 kHz, respectively. The thickness of the deposited PDMS layer is roughly around 20-25 μm. Nitrogen gas was blown on the PDMS during the laser ablation process to reduce oxidation. This enabled multiple usages of the same PDMS material for the laser ablation process. The contact angle of water on PDMS micro/nanoparticle deposited glass and aluminum substrate surfaces were 153.8° and 156.2° respectively, as shown in FIG. 5. The corresponding roll-off angles were 4.2° and 3.8°, respectively. The optical transmission of the superhydrophobic glass surfaces was measured to be around 75%. Glass with fully cured PDMS on it has an optical transmission of 89%, and plane glass has an optical transmission of 92%. A scotch tape test was performed to check the adhesion of the PDMS micro/nanoparticles to the substrate. The scotch tape was applied to the surface of the deposited PDMS micro/nanoparticles. The tape was then peeled off with a force of 20 N/cm². It was observed that the PDMS particles still stuck to the surface without any noticeable change in the contact angle.

PDMS Nano-Micro Particle Transfer onto the Aluminum Surface

The PDMS particles were transferred onto the aluminum surface using a laser energy density of 2.32 mJ/cm², a laser scan speed of 200 mm/s, and a spot size of ˜25 μm (1/e² diameter). The contact angle of PDMS nano-microparticles on the aluminum surface measured was around 155°, as shown in FIG. 5. The roll-off-angle was measured as 3.7°. The scotch tape test was also performed on the aluminum surface, and the PDMS surface still showed the superhydrophobic property.

### Selective Patterning of Deposited PDMS Micro/Nano Particles

This laser ablation technique can also be used for selective patterning of PDMS on different substrates. By varying the side-to-side line-spacing, selective deposition of PDMS “lines” can be done on various substrates. These “lines” are comprised of laser-ablated PDMS micro/nanoparticles that stick to the substrate and form a continuous film that is only around 35 μm wide and around 40-50 μm in thickness. This method could have potential applications in microfluidic channels and chips.

### Example 3: Detailed Results

### Laser Ablation Process Optimization

Different laser parameters were tested for the laser ablation process to determine the optimal condition to achieve superhydrophobic surfaces. It was found that scan speeds above 200 mm/s made the laser beam move too fast and did not ablate enough PDMS per unit area to create a superhydrophobic surface on the substrate. Hence, the laser scan speed was chosen to be 200 mm/s. The laser fluences were varied across a range of 1.1-2.3 J/cm², keeping the scan speed constant at 200 mm/s. FIGS. 4A-4E show the effect of varying laser fluence on the deposited PDMS micro/nanoparticles on the glass substrate. It was observed that at higher fluences, more PDMS particles get ablated and deposited on the substrate. It is necessary to have a certain number of PDMS micro/nanoparticles on the substrate to achieve superhydrophobicity. The substrate surface starts to show superhydrophobicity above 2 J/cm². The side-to-side line spacing and the frequency of the laser were kept constant at 20 μm, and the laser was operated at 50 kHz, respectively. Nitrogen gas was blown on the PDMS during the laser ablation process to reduce oxidation. This enabled multiple uses of the same PDMS material for the laser ablation process. The contact angle of water on PDMS micro/nanoparticle deposited glass, PMMA, and aluminum substrate surfaces were 153.8°±1.7°, 157.3°±2.1°, and 156.8°±1.6° respectively, as shown in FIG. 3. The corresponding roll-off angles were 4.2°, 3.1°, and 3.8°, respectively. The separation between the PDMS-coated top glass and the substrate on which the laser-ablated PDMS micro/nanoparticles were deposited was 1 mm.

### Plasma-Treated Glass Slides and Aluminum

The water contact angle (WCA) on a plane glass slide was found to be 43.4°±3.8°, and the WCA on a plasma-treated glass slide was found to be 23.3°±4.2°. Meanwhile, the aluminum surface was found to be mildly hydrophilic with water contact angles of 81.4±5.8°, and the WCA on the plasma-treated aluminum sample was found to be 19.3±3.6°. The decrease in the WCA can be attributed to an increase in the surface free energy due to the plasma treatment. The plasma treatment of glass also allows for achieving an increased bond between the PDMS and glass.

### Variation of the PDMS Micro/Nanoparticles Coating Thickness

As shown in FIG. 5, there are two spacers which are pieces of solid plastic separating the top glass coated with PDMS and the bottom substrate. Varying the thickness of the spacer varied the distance between the PDMS-coated top glass and the bottom substrate. This, in turn, affects the morphology of the laser-ablated PDMS micro/nanoparticles coating and its thickness.

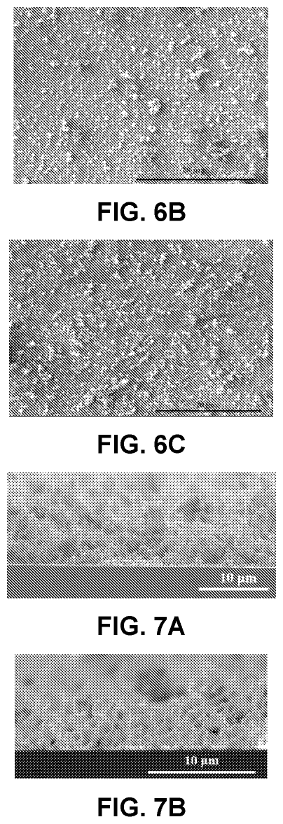

FIGS. 6A-6C show the different morphologies of the PDMS micro/nanoparticles coated surface at different spacer thicknesses. The laser fluence used was 2 J/cm². It can be seen that at a smaller spacer thickness, more particles are present on the surface. The sizes of the particles also vary, ranging from a few nanometers to a few microns. The surface stopped being superhydrophobic with a spacer thickness of more than 8 mm as the film was not continuous and very thin.

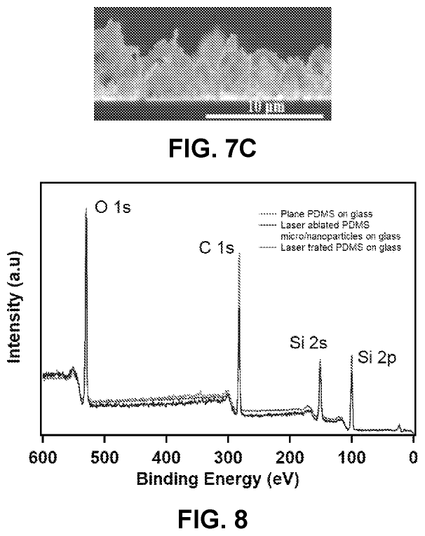

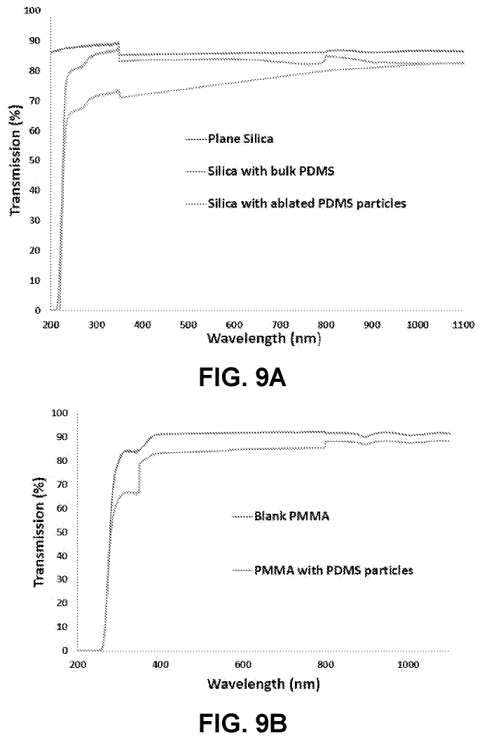

FIGS. 7A-7C show the thickness variation of the PDMS micro/nanoparticles coated surface at different spacer thicknesses. The average coating thickness gradually decreases with an increase in the spacer thickness. This is because, with increasing spacer thickness, a lesser number of laser-ablated PDMS micro/nanoparticles reach the substrate. It can be seen that the laser-ablated PDMS micro/nanoparticles deposited at a spacer thickness of 1 mm had the highest average thickness of around 8 μm, while that deposited at spacer thicknesses of 5 mm and 8 mm had average thicknesses of around 4 μm and 2 μm, respectively. The coating is non-uniform with a lot of thickness variations, as can be seen in FIGS. 9A-9B.

### Elemental Analysis of the Surface

FIG. 8 shows the XPS spectrum of the different PDMS samples using a monochromatic X-ray source (1486.6 eV). Plane PDMS on glass refers to the poured and partially cured (25 min.). PDMS on glass and then laser treated refers to the poured and cured (25 min.) PDMS on glass that has been ablated by the laser to deposit the PDMS micro/nanoparticles on the substrate. There is no noticeable change in the position of the peaks which indicates that there is no significant degradation of the PDMS.

The atomic percentage composition of the different elements is shown in Table 1. The carbon content of all the samples under consideration was found to remain fairly constant. The silicon content of the laser-treated PDMS on glass increased by around 5%, while the oxygen content of both the laser-ablated PDMS micro/nanoparticles and the laser-treated PDMS on glass reduced considerably. This can be attributed to the breaking and forming of bonds between elements due to laser-matter interaction.

TABLE 1
Elemental Composition (at %) of the Different Samples of PDMS

| | Elemental Composition (at %) | | |
|---|---|---|---|
| Sample | O 1s | C 1s | Si 2p |
| Plain PDMS on glass | 45.2 | 32.3 | 20.5 |
| Laser ablated PDMS micro/nanoparticles | 39.7 | 33.2 | 21.4 |
| Laser treated PDMS on glass | 33.4 | 33 | 26.6 |

### Optical Transmission Measurement

The optical transmission measurements are shown in FIGS. 9A-9B. On average, the optical transmission value of the cured PDMS on fused silica is less than that of plane fused silica by about 6-7%. On the other hand, the optical transmission value of the laser-ablated PDMS micro/nanoparticles coated fused silica is less than that of plane glass by around 15% on average. The optical transmission value of the laser-ablated PDMS micro/nanoparticles coated PMMA is less than that of uncoated PMMA by around 10% on average. The lower transmission of the laser-ablated PDMS micro/nanoparticles coated glass is mainly caused by the scattering of light by the PDMS particles. The ablated PDMS micro/nanoparticles coating was deposited at a spacer length of 8 mm and a laser fluence of 2 J/cm². Coatings deposited at shorter spacer lengths have more PDMS micro/nanoparticles on the surface and greater coating thickness; subsequently, they will have a lesser optical transmission value compared to the coating deposited at an 8 mm spacer length due to increased optical scattering. The optical transmission values reduce significantly in the shorter wavelength range due to increased light scattering at shorter wavelengths.

The laser-ablated PDMS micro/nanoparticles coated glass was placed on top of a solar cell, and the change in efficiency was measured. This was done to simulate a solar panel with laser-ablated PDMS micro/nanoparticles coated glass. The solar cell gave an efficiency of 4.45% with clear glass; meanwhile, the same solar cell gave an efficiency of 3.98% with the laser-ablated PDMS micro/nanoparticles coated glass. One sun illumination was used for the experiment. The solar cell used was a reference solar cell supplied by NREL with a rated efficiency of 4.49% under one sun illumination.

### Shear Strength of the PDMS Micro/Nanoparticle Coating at Different Coating Thicknesses

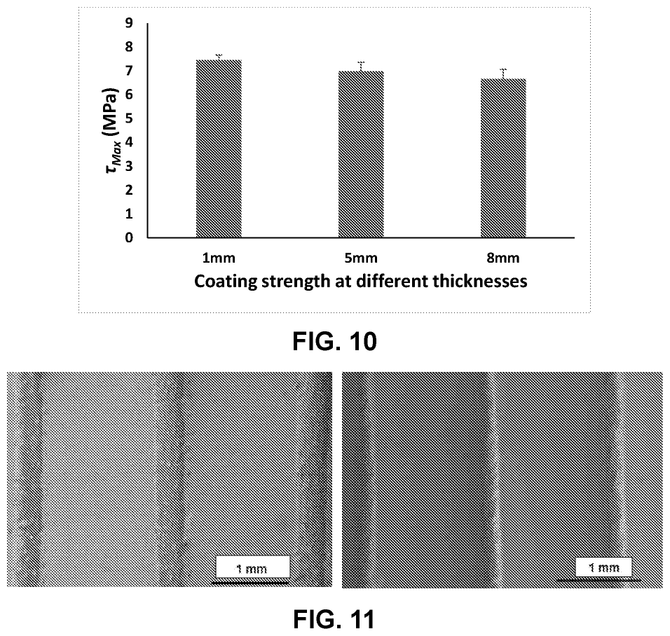

FIG. 10 shows the shear strength of the laser-ablated PDMS micro/nanoparticles coating at different spacer thicknesses. There is a slight variation in the coating shear strength with changing spacer thicknesses. The shear strength obtained at a spacer thickness of 5 mm is slightly lower than that at 1 mm by around 0.56 MPa, and the shear strength obtained at a spacer thickness of 8 mm is slightly lower than that at 5 mm by around 0.32 MPa. This can be attributed to the coating thickness variations with different spacer thicknesses. The coating deposited at 1 mm spacer thickness requires more force to be scraped off than the coating deposited at 5 mm spacer thickness. This is because the coating deposited at 1 mm spacer thickness is thicker than the coating deposited at 5 mm spacer thickness. The same reasoning can be applied to the coating deposited at 8 mm spacer thickness to account for the decreased shear strength.

### Patterning of PDMS Lines

The laser-ablated PDMS micro/nanoparticles deposition technique can also be used for patterned PDMS lines on different substrates, as shown in FIG. 11. A laser fluence of 2 J/cm² was used for the laser ablation process. The spacer thickness was 1 mm. These PDMS lines are composed of laser-ablated PDMS micro/nanoparticles that bond to the substrate and form a continuous film, and their width and spacing can be varied. This technique can be used to coat microchannels in microfluidic devices and make them superhydrophobic.

To make the PDMS line patterns on the substrate, two metal masks were used. The masks had openings in the shape of fingers. The length of these fingers was 2 mm, and the width of these fingers was 500 μm and 200 μm, respectively. The separation between the openings was 1.4 mm. Accordingly, the width of the PDMS lines was 500 μm and 200 μm, respectively, and the spacing between the deposited PDMS lines was roughly around 1.4 mm. The metal masks were placed on the surface of the glass substrates during the laser ablation process. Hence, the ablated PDMS micro/nanoparticles were deposited through the open areas of the mask. In the absence of the mask, the vaporized PDMS fragments generated from the laser ablation process would spread and settle across the entire surface of the substrate without forming any patterns of lines.

### Effect of Initial Curing Time of PDMS on the PDMS Lines

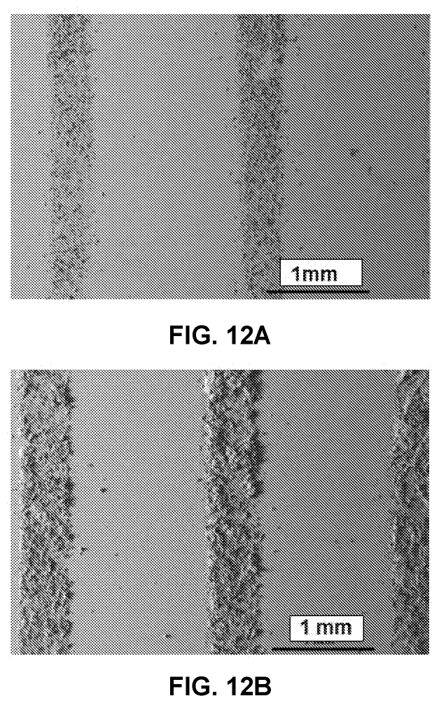

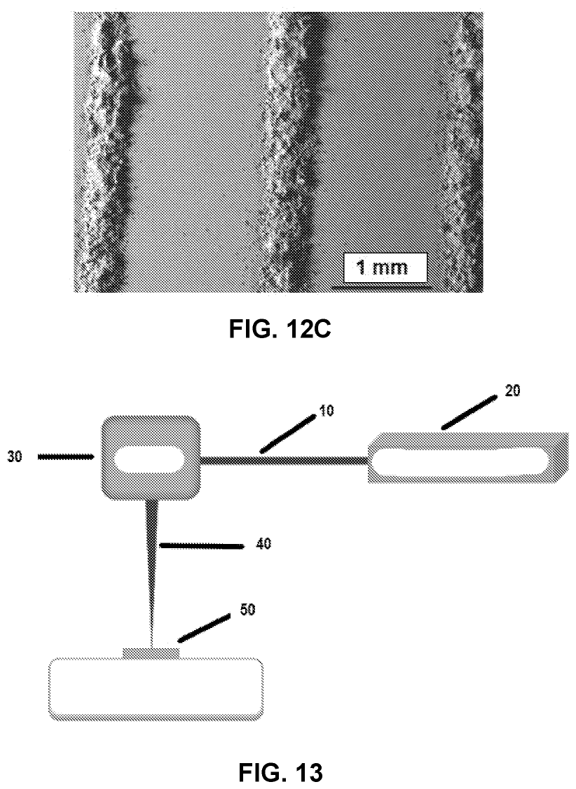

FIGS. 12A-12C show how the ablated PDMS micro/nanoparticles coating is affected by different curing times of the poured PDMS on glass. With lower curing times of the poured PDMS, the deposited PDMS lines become “broken” in certain places due to inhomogeneous particle distribution. It can be seen that a curing time of 25 mins. leads to a more consistent and uniform coating compared to curing times of 15 and 20 mins. No significant difference in the deposited PDMS lines was observed with curing times of more than 25 mins. If it is cured too long, it may not deposit and just decomposes. The spacer thickness used for the deposition of the PDMS lines was 1 mm. The substrate used was glass.

### Example 4: Discussion and Conclusion

PDMS has low optical absorption at 355 nm laser wavelength; however, by focusing the laser beam, ablation was produced, generating nano/micro particles. The laser transferred hydrophobic PDMS nano/micro particles can be deposited on various surfaces producing the microtextured hydrophobic film. The microtextured hydrophobic film shows superhydrophobic properties. Superhydrophobic properties of glass and aluminum surfaces have been demonstrated herein, and the method is applicable to a variety of materials. Due to the nanosecond laser pulse used in this study, the PDMS decomposition is not significant as it still shows superhydrophobic properties.

The PDMS microparticles are formed due to the laser pulses ablating from the top part of PDMS (as shown in FIG. 2C). The size of deposited PDMS particles is dependent upon the laser power. Lower laser power produces smaller particles of <1 μm in size, and higher laser power produces several micron size particles. Too high laser power could also change the chemical composition of the deposited particles. Also, the laser beam had a Gaussian profile, so it produced particles of different sizes. At a 50 kHz laser repetition rate and a beam scan speed of 500 mm/s, the distance between two deposited materials spot is 10 μm, so each spot receives the peak and tail of the Gaussian shape of the laser pulse. As seen in FIG. 4A, lower laser power produces very small ablation particles (<1 μm), which coat the surface relatively uniformly. The surface with small uniform particles changes the wetting properties of the water droplets and does not produce a superhydrophobic surface. With higher laser power, the pulse produces bigger particles (˜2-4 μm) and smaller particles due to Gaussian beam profile; hence the distribution of particle size is observed as seen in FIGS. 4B-4C. The bigger particles play an important role in introducing roughness.

The PDMS microparticles induce light scattering, and so the optical transmission was measured using He—Ne laser and thermal power detector. The detector is placed very close to the sample (shown in FIG. 3) to detect most of the scattered light. The highest optical transmission measured was 74.8%.

In this work, it was shown that pulsed laser ablated PDMS nano/micro particles can be deposited on various surfaces producing superhydrophobic thin films. The superhydrophobic properties of glass and aluminum surfaces are demonstrated herein, and the method is applicable to a variety of materials. The PDMS micro/nanoparticles are formed from laser ablation of the top part of the surface of the PDMS. This method can be used in the fabrication of microfluidic devices, and to create superhydrophobic surfaces for biomedical, solar, printing, fuel cell research, and many other applications.

Laser processing is used in various industrial sectors such as aerospace, automobile, electronics, photovoltaics, biomedical and general manufacturing. High power lasers are available at a relatively lower cost. Using our laboratory laser, it took 3 seconds to deposit PDMS on one square inch area. This could be reduced significantly by using higher-power commercial lasers. So, the method can be used for large-area preparation.

One of the factors that affect the laser-ablated PDMS micro/nanoparticles coating method is the curing of PDMS. The curing condition for the pristine PDMS is roughly two days at room temperature, 45 min. at 100° C., 20 min. at 125° C., or 10 min. at 150° C. Uncured or semi-cured PDMS is viscous and is liquid compared to its cured counterpart. Hence, when semi-cured PDMS is subjected to laser irradiation, fewer particles are ablated and ejected in comparison with cured PDMS. This results in inconsistencies in the ablated PDMS micro/nanoparticles coating. The superhydrophobicity of the laser-ablated PDMS micro/nanoparticles coated surface is due to the hierarchical scale roughness of the surface combined with the low surface free energy of PDMS.

The laser ablation of the PDMS occurs through thermal, thermo-oxidative, and mechanical reactions, resulting in the evaporation of macromolecular fragments. After these fragments are released, they come in contact with the substrate and settle on the surface, forming a thin coating of PDMS micro/nanoparticles. The farther the substrate from the laser-ablated PDMS, the lesser the fragments that reach the substrate due to the spreading of the vapor. The efficiency of the PDMS laser ablation process depends on the amount of absorbed light energy. Laser radiation absorption is described by Bouguer-Lambert law:

$$I ( z ) = {I}_{0} η exp ( - χ z ) \qquad ( 2 )$$

where I₀—is the incident laser intensity on the surface; χ—is an absorption coefficient of PDMS at the laser wavelength; z—is the coordinate measured into the depth of the material; η—is the coefficient determining the absorbed energy share.

Energy absorbed in the sample layer during time t:

$$E = S {\int }_{0}^{t} I ( z ) dt = S η {I}_{0} exp ( χ z ) t \qquad ( 3 )$$

where S—is the cross-sectional area of the laser beam on the sample surface. The intensity lost in a layer of thickness z:

$$Δ I = {I}_{0} - I ( z ) = {I}_{0} ( 1 - η ) exp ( - χ z ) \qquad ( 4 )$$

Using equation (3) and the PDMS absorption coefficient value of 7.38 at 355 nm [35], the energy absorbed by the PDMS layer at a fluence of 2 J/cm2 was found to be 7.41 J. The robustness/adhesion of the laser-ablated PDMS particles to the substrate is a critical consideration. The mechanical robustness of the laser-ablated PDMS micro/nanoparticle coating can be improved by modifying the uncured PDMS solution by adding epoxy or reinforcing it with nano-silica hybrid nanofillers or both. The uncured PDMS solution can also be blended with polymers like polyurethane (PU) to enhance the mechanical properties of the laser-ablated PDMS micro/nanoparticles coating. Shear strength values of over 40 MPa can be potentially achieved by these improved methods. Generally, PDMS coatings display low adhesion strength in comparison to metals due to their non-polar nature and low surface free energy. However, the bonding of the PDMS micro/nanoparticle coating to the aluminum and glass surface can be attributed to micromechanical adhesion. When the laser ablated PDMS micro/nanoparticles land on the substrate surface, they fill the microvoids, rugosity, and pores on the surface forming mechanically interlocked bonds. Other factors, like attractive electrostatic forces, may also enhance the bonding.

The scattering of the PDMS particles on the substrate surface could be a concern during the laser ablation process. There are a few scattered stray PDMS particles in between the PDMS lines. This can be avoided by firmly placing the metal mask on the substrate and minimizing the spreading of the laser-ablated PDMS macromolecular fragments underneath the mask.

The laser-ablated PDMS micro/nanoparticles technique offers a versatile approach for creating superhydrophobic surfaces, which find extensive applications in various fields such as aerospace, defense, automotive, biomedical, engineering, sensors, apparel, anti-freeze surfaces, anti-fog coating, anti-bacterial surfaces, and more. This method allows for the generation of patterns or localized superhydrophobic regions, enabling the fabrication of superhydrophobic patches. Additionally, it holds significant potential to enhance the efficiency of fluid flow and reduce resistance in microfluidic systems.

### CONCLUSION

In this work, it was shown that pulsed laser ablated PDMS nano/micro particles can be deposited on various surfaces producing superhydrophobic thin films. The superhydrophobic properties of glass and aluminum surfaces have been demonstrated, and the method is applicable to a variety of materials. The PDMS micro/nanoparticles are formed from laser ablation of the top part of the surface of the PDMS. This method can be used in the fabrication of microfluidic devices, and to create superhydrophobic surfaces for biomedical, solar, printing, fuel cell research, and many other applications.

### Example 5: Surface Texturing Experiments

### Materials

The substrates used were microscope glass slides (Height=3 inches; Width=1 inch; Thickness=0.04 inches) by Amscope, recrystallized silicon-carbide ceramic sheets (Height=3 inches; Width=3 inches; Thickness—0.125 inches), and aluminum alloy (Al 7075) micromachined samples (Height=1 inch; Width=1 inch; Thickness—0.07 inches) polished down to roughness of less than 1 μm. The chemical composition by weight of Al 7075 was Zn=5.4%, Cu=1.42%, Mn=0.12%, Mg=2.42%, Fe=0.42%, Cr=0.21%, Ti=0.11%, Si=0.13%, and Al =89.77%. Both the aluminum and silicon-carbide were purchased from McMaster-Carr.

### Sample Preparation Procedure

A 355 nm wavelength nanosecond pulsed laser was used to texture the aluminum. The 355 nm wavelength 20 nanoseconds pulsed width laser from Coherent Matrix 355-8-50, operated at 50 kHz pulse repetition rate, at 8 W average power, was used in this study. To texture the glass, a 355 nm wavelength picosecond pulsed laser from Spectra-Physics IceFyre 355-30, operated at 1 MHz, at 30 W average power, was used. The pulse width of the picosecond laser is 15 picoseconds. Both the glass and aluminum surfaces underwent texture modification using different fluences. The glass surface was textured with two different fluences, namely 1.75 J/cm² and 2.25 J/cm². Similarly, the aluminum surface was also textured using the same two fluences, 1.75 J/cm² and 2.25 J/cm².

The setup of the lasers is shown in FIG. 1. High Dynamics PIMag linear XY stages were used for mounting the samples, and the laser beam was scanned using the Sino-Galvo SG7210 system. Each of the textured areas were 2 cm in length, and 0.4 cm in width. After the laser texturing process, the samples were treated with plasma (Jelight Company UVO-Cleaner Model 18) for 10 min. The plasma treatment removes all organic matter from the surface.

The UV laser is chosen for this experiment because metals and ceramics reflect most of the laser energy from longer wavelength lasers. Additionally, shorter pulse lasers are good candidates for laser texturing. The experimental setup has been shown in FIG. 13.

### Water Flow Testing Procedure

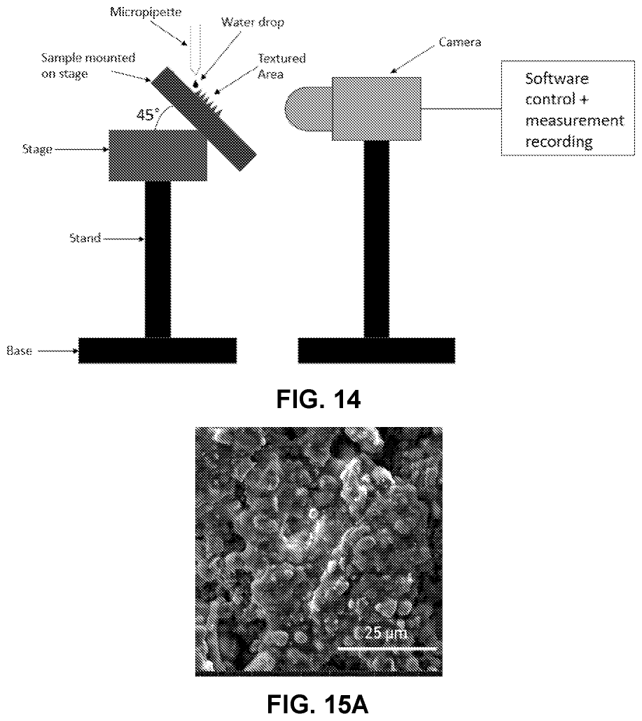

After the plasma treatment, each of the samples were inclined at an angle of 45° and a drop of water (10 μL) was dropped on one end of the textured area. Then, the movement of the water was observed as the water flowed across the length of the textured area. As a reference, a drop of water (10 μL) was also dropped on a smooth untextured area of each of the samples and the water flow was observed. The time taken by the water to traverse/completely wet the length of the textured area was observed with a camera and recorded. The schematics of the experimental setup has been shown in FIG. 14.

### Surface Characterization

The surface analysis of the laser-ablated surface done by using FEI Quanta 650 Field Emission Microscope. The water contact angle measurements were done using the Ram6-Hart Model 250 Goniometer.

### Results and Discussion

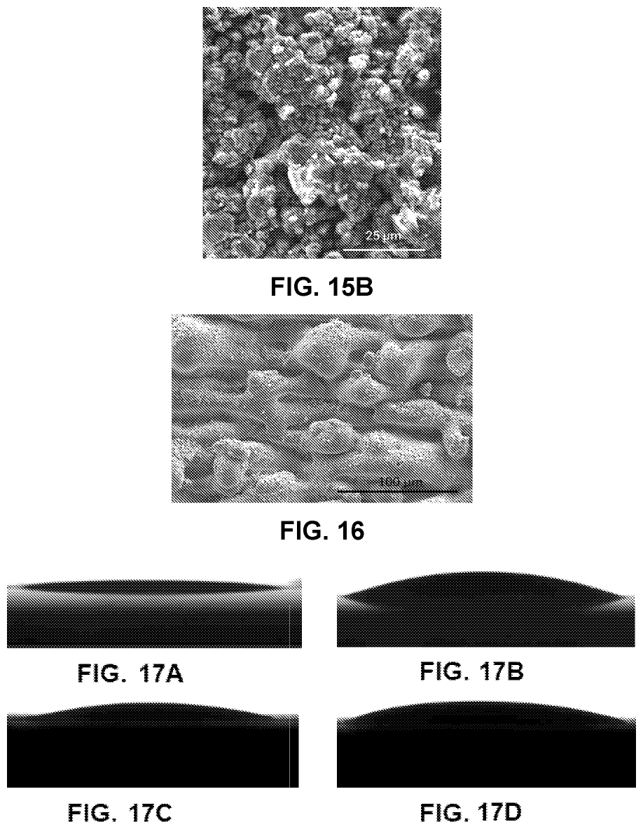

Variation of the Speed of Water Flow on Textured Surfaces Before and After Plasma Treatment. Modifying the surface texture has a direct impact on the spreading behavior of water, influencing the speed of water flow. It has been observed that increasing the fluence, which consequently increases the average feature height, leads to a higher rate of water flow compared to surfaces textured with lower fluence. FIGS. 15A-16 depict the surfaces of aluminum at various fluences. The speed of the flow of water was observed before and after the plasma treatment on the textured surfaces. It was observed that the plasma treatment increased the speed of the water flow.

The entire length of the textured area is 2 cm and the measurements of the time taken to traverse/wet were done in steps of 0.5 cm, 1 cm, 1.5 cm and 2 cm before and after the plasma treatment. Also, the time taken to traverse 2 cm on a smooth untextured surface was also calculated before and after the plasma treatment. For the aluminum surface textured at 2.25 J/cm2, the traversal times for distances of 0.5 cm, 1 cm, 1.5 cm, and 2 cm were less than 1 second, 1.5 seconds, 3 seconds, and 4.5 seconds, respectively. On the other hand, for the aluminum surface textured at 1.75 J/cm², the corresponding traversal times were 1.5 seconds, 3 seconds, 5 seconds, and 7 seconds, respectively. In the case of the glass surface textured at 2.25 J/cm², the time required to traverse distances of 0.5 cm, 1 cm, 1.5 cm, and 2 cm was less than 1 second, 1 second, 2 seconds, and 2.5 seconds, respectively. Similarly, for the glass surface textured at 1.75 J/cm2, the traversal times for distances of 0.5 cm, 1 cm, 1.5 cm, and 2 cm were 1 second, 1.5 seconds, 3 seconds, and 4 seconds, respectively.

Contact Angles. The water contact angle (WCA) on glass and aluminum surfaces textured at a fluence of 2.25 J/cm² were found to be 17.2°±1.8° and 25.2°±1°, respectively. On the other hand, glass and aluminum surfaces textured at a fluence of 1.75 J/cm² had a water contact angle (WCA) of 23.4°±0.9° and 28.2°±0.6°. The contact angles have been depicted in FIGS. 17A-17D. The greater wetting observed at higher fluences can be attributed to the increased penetration of the water droplet into the surface texture. This enhanced penetration leads to the formation of an even thinner water film and results in a more pronounced Wenzel wetting behavior. After the plasma treatment, all the surfaces displayed WCA of less than 1°. The decrease in the WCA can be attributed to an increase in the surface free energy due to the plasma treatment.

Dust Removal after Plasma Treatment. Superhydrophilicity is recognized for its ability to enhance self-cleaning properties, facilitating the removal of dirt and dust from the surface through the spreading of water. In terms of preventing soiling or the accumulation of dirt and contaminants, the superhydrophilic surface offers a significantly higher efficiency, approximately 2.5 times greater, compared to a superhydrophobic surface. Plasma treatment further enhances this behavior by promoting water spreading. To investigate this, an experiment was conducted by placing dirt particles on both the textured surface treated with plasma and an untreated surface. Subsequently, water droplets were applied to the surfaces, and the flow of the droplets was observed. The results revealed that on the plasma-treated textured surface, the water droplet effectively carried away the dirt particles to a greater extent compared to the untreated surface. Consequently, the plasma-treated textured surface exhibited a higher level of cleanliness compared to the untreated surface.

Longevity of the Plasma Effect. When assessing the practical application potential of superhydrophilicity, the stability of this property becomes a crucial consideration. To determine the degradation of superhydrophilicity of the plasma treated surfaces, changes in water contact angles over time were investigated. The experimental findings revealed that on glass surfaces, the water contact angles exhibited an average increase of 3-4 degrees within a 12-hour period, and a further average increase of 7-8 degrees after 24 hours. After the 24-hour mark, the contact angles reached a point of stability with no further changes observed. Similarly, on aluminum surfaces, the contact angles increased by an average of 6-7 degrees within 12 hours, and further increased by an average of 14-16 degrees after 24 hours. Like the glass surfaces, the contact angles on aluminum surfaces also reached a state of stability after the 24-hour duration.

### Example 6: Microtexturing with Laser to Make Superhydrophilic Surfaces

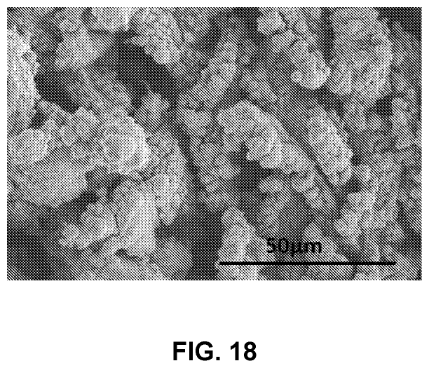

The 355 nm can be used to microtexture aluminum surface. A hatch pattern was drawn on the aluminum surface at a laser scan speed of 60 mm/s and a frequency of 50 kHz. The power used was 3 J/cm². The resulting surface has been shown in FIG. 18. The microtextured surface is superhydrophilic with contact angle of less than 1 degree. PDMS can be deposited on the microtextured surface by evaporation or by the laser ablation method to make the surface superhydrophobic (e.g., contact angle of about 170°). Afterwards, laser can be used to remove the PDMS coating to make the surface back into superhydrophilic (i.e., reversible superhydrohilicity-superhydrophobicity). The power of the laser can be controlled in a way so that it does not affect the aluminum surface but just removes the coating from the top. A power of 0.75 J/cm² was used using the 355 nm laser to remove the PDMS coating. This method of creating reversible superhydrophilic-superhydrophobic surface can be applied to other materials like metals, alloys, polymers, ceramics, and alloys.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

### REFERENCES

1. Adera, S., et al. Non-wetting droplets on hot superhydrophilic surfaces. Nat Commun 4, 2518 (2013).
2. Agbe, H. et al, “Tunable superhydrophobic aluminum surfaces with anti-biofouling and antibacterial properties”, Coatings, 10, 982 (2020).
3. Ahmad, I. et al, A review on development and applications of bio-inspired superhydrophobic textiles, Materials, 9, 8923, (2016).
4. Al-Harbi L. M.; et al. Controlled Preparation of Thermally Stable Fe-Poly(dimethylsiloxane) Composite by Magnetic Induction Heating. Polymers (Basel) 2018 10(5),507-515.
5. Ali, H. M.; et al. Techniques for the Fabrication of Superhydrophobic Surfaces and Their Heat Transfer Applications; (Intechopen, Online), 2018.
6. Arnold, N.; et al. Model for laser-induced thermal degradation and ablation of polymers. Appl.
   Phys. A 1999 68, 615-625.
7. Bai, Q., et al. Drag reduction characteristics and flow field analysis of textured surface. Friction 4, 165-175 (2016).
8. Bao, L.; et al. Effect of surface free energy and wettability on the adhesion property of waterborne polyurethane adhesive. RSC Adv. 2016 6, 99346-99352.
9. Barati Darband, G H.; et al. Science and Engineering of Superhydrophobic Surfaces: Review of Corrosion Resistance, Chemical and Mechanical Stability, Arab. J. Chem. 2020, 13, 1763-1802.
10. Bico, J., et al. Wetting of textured surfaces. Colloids surf. A: Physicochem. Eng. Asp. 206, 41-46 (2002).
11. Chakraborty, A. et al, Superhydrophobic surfaces by microtexturing: A critical review, Reviews of Adhesion and Adhesives, 9, 35-64 (2021).
12. Chau, K.; et al. Dependence of the quality of adhesion between poly(dimethylsiloxane) and glass surfaces on the composition of the oxidizing plasma. Microfluid. Nanofluid. 2011 10 907-917.
13. Chu F.; et al. Fabrication and condensation characteristics of metallic superhydrophobic surface with hierarchical micro-nano structures. Appl. Surf. Sci. 2016 371,322-328.
14. Cortese, B.; et al. Superhydrophobicity Due to the Hierarchical Scale Roughness of PDMS Surfaces. Langmuir 2018 24 (6), 2712-2718.
15. Drelich, J., et al, Hydrophilic and superhydrophilic surfaces and materials, Soft Matter, 7, 2011, 9804-9828.
16. Esmaeilirad A.; et al. A cost-effective method to create physically and thermally stable and storable superhydrophobic aluminum alloy surfaces. Surf. Coat. Technol.. 2016 285,227-234.
17. Greczynski, G.; et al. X-ray photoelectron spectroscopy: Towards reliable binding energy referencing. Prog. Mat. Sci. 2020 107, 2020, 100591-100637.
18. Gregory, D B, et al. Shark skin inspired low-drag microstrurctured surfaces in closed channel flow. J Colloid Interface 393: 384-396 (2013)
19. Gupta, M. et al “METHOD OF FORMING A SPECTRAL SELECTIVE COATING”, U.S. Pat. No. 10,201,947, Feb. 12, 2019.
20. Gupta, M. C. “Laser-induced surface modification for photovoltaic device applications,” Handbook of Laser Micro-and Nano-Engineering, pg. 829-856, Springer, 2020.
21. Gupta, M. C. et al “Conducting Nanotubes or Nanostructures Based Composites, Method of Making Them and Applications”, U.S. Pat. No. 8,424,200, Apr. 23, 2013.
22. Gupta, M. C. et al “Conducting Nanotubes or Nanostructures Based Composites, Method of Making Them and Applications”, WO 2008/045109, Apr. 17, 2008.
23. Gupta, M. C. et al “Micro-Structure and Nano-Structure Replication Methods and Article of Manufacture”, U.S. Pat. No. 10,131,086, Nov. 20, 2018.
24. Gupta, M. C. et al “Systems and Methods of Laser Texturing and Crystallization of Material Surfaces”, U.S. Pat. No. 8,753,990, Jun. 17, 2014.
25. Gupta, M. C. et al “Systems and Methods of Laser Texturing of Material Surfaces and their Applications”, US Publication No. 2010/0143744, Jun. 10, 2010.
26. Gupta, M. C. et al “Systems and Methods of Laser Texturing of Material Surfaces and their Applications”, WO 2008/127807, Oct. 23, 2008.
27. Gupta, M.C.; et al. Ice adhesion and anti-icing using microtextured surfaces, ice adhesion: mechanism, measurement, and mitigation; Wiley: New York 2020, 389-417.
28. Gupta, M. C. et al, “Laser processing of materials for renewable energy applications,” MRS Energy & Sustainability, 2, (2015).
29. Gupta, M. C. et al, “Systems and Methods of Laser Texturing and Crystallization of Material Surfaces”, WO 2008/091242, Jul. 31, 2008.
30. Gupta, M. C. et al, “SYSTEMS AND METHODS OF LASER TEXTURING OF MATERIAL SURFACES AND THEIR APPLICATIONS”, U.S. Pat. No. 8,846,551, Sep. 30, 2014.
31. Gupta, M. C. et al. “Systems and Methods of Laser Texturing and Crystallization of Material Surfaces”, US Publication No. 2014/0273535, Sep. 18, 2014.
32. Gupta, M. C. et al., “COMPOSITION AND METHOD FOR A MICROTEXTURE HYDROPHOBIC OR SUPERHYDROPHOBIC COATING”, US Publication 2021/0154700 A1, May 27, 2021.
33. Hamdi, M.; et al. Improving the adhesion strength of polymers: effect of surface treatments.
   J. Adhes. Sci. Technol. 2020 34, 1853-1870.
34. Jeevahan, J. et al, “Superhydrophobic surfaces: a review on fundamentals, applications, and challenges,” Journal of Coatings Technology and Research, 15, 231 (2018).
35. Jia X.; et al. Fabrication of non-flaking, superhydrophobic surfaces using a one-step solution-immersion process on copper foams. Appl. Surf. Sci.2013 286, 220-227.
36. Jiang, T.; et al. Ultrashort picosecond laser processing of micro-mols for fabricating plastic parts with superhydrophobic surfaces. Appl. Phys. A. 2012 108, 863-869.
37. Kouser, T. et al, “Contribution of superhydrophobic surfaces and polymer additives to drag reduction”, ChemBioEng Rev. 2021, 8:337-356.
38. Krüger, R. et al, Surface cleaning by plasma-enhanced desorption of contaminants (PEDC), Surface and Coatings Technology, Volume 112, Issues 1-3,1999,Pages 240-244.
39. Kunizhev, B. I.; et al. Destruction of polymers under the action of laser radiation. 2021 IOP Conf. Ser.: Mater. Sci. Eng. 1083-1089.
40. Li, C. et al, “Li-air battery with a superhydrophobic Li-protective layer,” ACS Applied Materials and Interfaces, 12, 120 (2020).
41. Liu, B.; et al. Study on hierarchical structured PDMS for surface superhydrophobicity using imprinting with ultrafast laser structured models.Appl. Surf. Sci. 2016 364, 528-538.
42. Lockwood, D. J. Rayleigh, and Mie Scattering. In: Luo, M.R. (eds) Encyclopedia of Color Science and Technology; Springer, New York, New York 2016, 1097-1107.
43. Lundeval, A.; et al; Improved glass bonding with plasma treatment. Appl. Adhes. Sci. 2018 6, 4959-4970.
44. Manoharan, K.; et al. Superhydrophobic surfaces review: Functional application, fabrication techniques and limitations. J. Micromanuf. 2019, 2, 59-78.
45. Muharrem, T.; et al. Investigation of corrosion and thermal behavior of PU-PDMS-coated AISI 316L. e-polymers 2021 21, 355-365.
46. Mulrooney, A.; et al. Optically transparent superhydrophobic polydimethylsiloxane by periodic surface microtexture. Surf. Coat. Tech. 2017 325, 308-317.
47. Nundy, S. et al, Hydrophilic and Superhydrophilic Self-Cleaning Coatings by Morphologically Varying ZnO Microstructures for Photovoltaic and Glazing Applications, ACS Omega 2020 5 (2), 1033-1039.
48. Otitoju, T. A. et al, Superhydrophilic (superwetting) surfaces: A review on fabrication and application, Journal of Industrial and Engineering Chemistry, Volume 47, 2017, Pages 19-40.
49. Park, S.; et al. Production of an EP/PDMS/SA/AlZnO Coated Superhydrophobic Surface through an Aerosol-Assisted Chemical Vapor Deposition Process. Langmuir 2022 38 (25), 7825-7832.
50. Parvate, S. et al, “Superhydrophobic surfaces: insights from theory and experiment,” Phys. Chem. B, 124, 8, 1323 (2020).
51. Patel, P., et al, Superhydrophilic Surfaces for Antifoqging and Antifouling Microfluidic Devices, SLAS Technology, 15, 2010, 114-119.
52. Qin, C. et al, “Anti-icing epoxy resin surface modified by spray coating of PTFE Teflon particles for wind turbine blades”, Materials Today Communications, 22, 100770 (2020).
53. Quéré, D. Wetting and roughness. Annu. Rev. Mater. Res. 38, 71-99 (2008).
54. Sarbada, S.; et al. Superhydrophobic contoured surfaces created on metal and polymer using a femtosecond laser. Appl. Surf. Sci. 2017 405 465-475.
55. Sarkin, A. S. et al, “A review of anti-reflection and self-cleaning coatings on photovoltaic panels”, Solar Energy, 199, 63 (2020).
56. Stankova, N. E. et al, “Optical properties of polydimethylsiloxane (PDMS) during nanosecond laser processing,” Applied Surface Science, 374, 96 (2016).
57. Su, X.; et al. Polydimethylsiloxane-based superhydrophobic surfaces on steel substrate: fabrication, reversibly extreme wettability and oil-water separation. ACS Appl. Mater.

### Interfaces 2017 9, 3131-3141.

58. Su, X.; et al. Vapor-liquid sol-gel approach to fabricating highly durable and robust superhydrophobic polydimethylsiloxane@silica surface on polyester textile for oil-water separation. ACS Appl. Mater. Interfaces 2017 9, 28089-28099.
59. Tropmann, A.; et al.; Completely superhydrophobic PDMS surfaces for microfluidics.

### Langmuir 2012 28, 8292-8295.

60. Ueda, E., et al, Emerging Applications of Superhydrophilic-Superhydrophobic Micropatterns, Advanced Materials, 25, 2013, 1234-1247.
61. Vazirinasab, E. et al, “Application of superhydrophobic coatings as a corrosion barrier: A review,” Surface and Coatings Technology, 341, 40 (2018).
62. von Fraunhofer, JA. Adhesion and cohesion. Int. J. Dent. 2012, 2012, 951324-951332.
63. Vudayagiri, S.; et al. Factors affecting the surface and release properties of thin polydimethylsiloxane films. Polym. J. 2013 45, 871-878.
64. Wang H, et al. Influence of Surface Preprocessing on 4H—SiC Wafer Slicing by Using Ultrafast Laser. Crystals. 2023; 13(1):15.
65. Wang, X.; et al. Robust, hydrophobic anti-corrosion coating prepared by PDMS modified epoxy composite with graphite nanoplatelets/nano-silica hybrid nanofillers. Surf. Coat. Tech. 2021 421, 127440-127442.
66. Wenzel, R. N. Resistance of solid surfaces to wetting by water. Ind. Eng. Chem. 28, 988-994 (1936)
67. Wu, Y.; et al. Preparation and characterization of superhydrophobic surface based on polydimethylsiloxane (PDMS), J. Adhes. Sci. Technol. 2019 33(17), 1870-1881.
68. Xiao Gong, X.; et al. Highly Durable Superhydrophobic Polydimethylsiloxane/Silica Nanocomposite Surfaces with Good Self-Cleaning Ability, ACS Omega 2020 5 (8), 4100-4108.
69. Xiong, L, et al, “Adhesion promotion between PDMS and glass by oxygen plasma pre-treatment”, J Ades. Sci. Tech., 44 1046-1054 (2013).
70. Zhang, D. et al,4.06—Laser Ablation, Editor(s): Saleem Hashmi, et al, Comprehensive Materials Processing, Elsevier,2014,Pages 125-169.
71. Zhao J.; et al.; Superhydrophobic surfaces of SiO2-coated SiC nanowires: Fabrication, mechanism and ultraviolet-durable superhydrophobicity. J. Colloid Interface Sci.. 2015 444,33-37.
72. Zheng, L., et al. Superhydrophobicity from microstructured surface. Chin. Sci. Bull. 49, 1779-1787 (2004).

1. A method for producing a superhydrophobic surface on an article, the method comprising laser depositing hydrophobic materials on at least one surface of the article.

2. The method of claim 1, wherein the method comprises
(a) applying a coating of the hydrophobic material on a second surface of a first glass substrate having a first surface and a second surface;
(b) positioning the second surface of the first glass substrate in proximity to a first surface of a target substrate; and
(c) applying a depositing laser to the first surface of the first glass substrate, wherein the hydrophobic material on the second surface of the first glass substrate are converted to hydrophobic particles and deposited on the first surface of the target substrate.

3. The method of claim 1, wherein the hydrophobic material comprises a polysiloxane, a polyolefin, or a fluorinated polymer.

4. The method of claim 1, wherein the hydrophobic material comprises a dialkylpolysiloxane, polytetrafluoroethylene (PTFE), polyethylene, or a fluorinated ethylene propylene (FEP).

5. (canceled)

6. The method of claim 1, wherein the hydrophobic material comprises polydimethylsiloxane (PDMS).

7. The method of claim 2, wherein the hydrophobic material further comprises a curing agent, wherein the hydrophobic material and the curing agent composition are a mixture in a ratio of from 5:1 ratio (v/v) to 15:1 (v/v).

8. (canceled)

9. (canceled)

10. The method of claim 2, wherein prior to step (a), microtexturizing the first surface of the target substrate.

11. The method of claim 10, wherein
the first surface of the target substrate is subjected to a pulsed laser across the first surface at a controlled overlap of each pulsed laser to produce the microtextured surface, or
the pulsed laser has a wavelength range of about 250 nm to about 11,000 nm, or
the pulsed laser has an average power of about 1W to about 1,000 W, or
the pulsed laser has a pulse frequency range of about 1 Hz to about 100 MHz, or
the pulsed laser has a pulse energy of from about 1 μJ to about 100 J, or
the pulsed laser has a diameter in the range of about 1 μm to about 100 mm, or
the first surface of the target substrate is subjected to the pulsed laser at a scanning rate of from about 0.1 mm/s to about 10,000 mm/s, or
the overlap between each pulsed laser along a direction of scanning is from about 0% to about 99.5%.

12-18. (canceled)

19. The method of claim 2, wherein prior to step (c), the first surface of the target substrate is treated with a high-energy discharge treatment comprising a flame treatment, a corona treatment, a plasma treatment, or a combination thereof.

20. The method of claim 2, wherein prior to step (b), the coating of hydrophobic material is heated at a temperature of from about 75° C. to about 125° C.

21. The method of claim 2, wherein the first glass substrate comprises borosilicate, fused silica or sapphire.

22. The method of claim 2,
wherein in step (b), the second surface of the first glass substrate is from about 10 μm to about 10 mm to the first surface of the target substrate, or
wherein in step (b), one or more spacers are positioned between the second surface of the first glass substrate and the first surface of the target substrate.

23. (canceled)

24. The method of claim 2, wherein the depositing laser is an ultraviolet laser or an infra-red laser.

25. (canceled)

26. The method of claim 2, wherein
the depositing laser is applied to the first surface of the first glass substrate at a scan speed of from about 1 mm/s to about 1000 mm/s, or
the depositing laser has an average power of from about 1 W to about 100 W, or
the depositing laser has a beam size of from about 1 μm to about 10,000 μm, or
the depositing laser has a frequency of about 1 Hz to about 100 MHz, or
the depositing laser has a pulse energy of from about 1 μJ to about 100 J, or
the depositing laser is applied to the first surface of the first glass substrate at a line spacing of about 1 μm to about 10,000 μm.

27-31. (canceled)

32. The method of claim 2, further comprising blowing an inert gas on the coating of the hydrophobic material during step (c).

33. (canceled)

34. The method of claim 2, wherein after step (c), curing the hydrophobic particles deposited on the first surface of the target.

35. The method of claim 2, wherein after step (c), heating the hydrophobic particles deposited on the first surface of the target substrate at a temperature of from about 25° C. to about 250° C.

36. The method of claim 2, wherein
the hydrophobic particles are deposited on the target substrate in a layer having a thickness of from about 1 nm to about 10 μm thick, or
the hydrophobic particles have an average size of from about 1 nm to about 10 μm, or
the hydrophobic particles are deposited on the first surface of the target substrate in a patterned formation.

37. (canceled)

38. (canceled)

39. The method of claim 2, wherein the target substrate comprises glass, aluminum, metals, polymers, ceramics, composites, alloys or any combination thereof.

40. A superhydrophobic article made by the method of claim 1.

41-51. (canceled)
